(19) United States
(12) Patent Application Publication
(10) Pub. No.: US 2025/0220829 A1
(43) Pub. Date: Jul. 3, 2025

(54) EXTENSION STORAGE MODULES FOR CHANGING FORM FACTOR OF STORAGE DEVICES, AND STORAGE DEVICES INCLUDING THE SAME

(71) Applicant: Samsung Electronics Co., Ltd., Suwon-si (KR)

(72) Inventors: Jiwon Park, Suwon-si (KR); Seongyong Lee, Suwon-si (KR)

(21) Appl. No.: 18/806,945

(22) Filed: Aug. 16, 2024

(30) Foreign Application Priority Data
Dec. 27, 2023 (KR) 10-2023-0192210

(51) Int. Cl. H05K 5/00

(52) U.S. Cl. CPC H05K 5/0065

(57) ABSTRACT

A storage device comprising: a main storage module; and an extension storage module comprising: a substrate; a functional block on the substrate, wherein the functional block is configured to provide a first function for the main storage module; a control circuit on the substrate, wherein the control circuit is configured to control the functional block; a housing that extends around the substrate, the functional block, and the control circuit; and a connector that is connected to the substrate, wherein the connector is configured to provide an electrical connection and a physical connection between the extension storage module and the main storage module, wherein the extension storage module is electrically and physically attachable to and detachable from the main storage module through the connector, and wherein in response to the extension storage module being detached from the main storage module, the main storage module has a first form factor.

### CROSS-REFERENCE TO RELATED APPLICATIONS

This application claims priority under 35 USC § 119 to Korean Patent Application No. 10-2023-0192210 filed on Dec. 27, 2023 in the Korean Intellectual Property Office (KIPO), the contents of which are herein incorporated by reference in their entirety.

### BACKGROUND OF THE INVENTION

### 1. Technical Field

Example embodiments relate generally to semiconductor integrated circuits, and more particularly to extension storage modules for changing form factors of storage devices, and storage devices such as solid state drive (SSD) devices including the extension storage modules.

### 2. Description of the Related Art

Certain types of data storage devices may include one or more semiconductor memory devices. Examples of such data storage devices include solid state drives (SSDs). These types of data storage devices may have various design and/or performance advantages over hard disk drives (HDDs). Examples of potential advantages may include the absence of moving mechanical parts, higher data access speeds, stability, durability, and/or low power consumption. Recently, various systems, e.g., a laptop computer, a car, an airplane, a drone, etc., have adopted the SSDs for data storage.

### SUMMARY OF THE INVENTION

At least one example embodiment of the present disclosure provides an extension storage module capable of efficiently changing a form factor of a storage device without excessive design changes.

At least one example embodiment of the present disclosure provides a storage device and a solid state drive (SSD) device including the extension storage module.

According to example embodiments, a storage device comprising: a main storage module; and an extension storage module comprising: a substrate; a functional block on the substrate, wherein the functional block is configured to provide a first function for the main storage module; a control circuit on the substrate, wherein the control circuit is configured to control the functional block; a housing that extends around the substrate, the functional block, and the control circuit; and a connector that is connected to the substrate, wherein the connector is configured to provide an electrical connection and a physical connection between the extension storage module and the main storage module, wherein the extension storage module is electrically and physically attachable to and detachable from the main storage module through the connector, and wherein in response to the extension storage module being detached from the main storage module, the main storage module has a first form factor.

According to example embodiments, a storage device comprising: a main storage module that has a first form factor; and an extension storage module that is configured to be electrically and physically attachable to and detachable from the main storage module, wherein the extension storage module comprises: a first substrate; a functional block on the first substrate, wherein the functional block is configured to provide a first function for the main storage module; a control circuit on the first substrate, wherein the control circuit is configured to control the functional block; a first housing that extends around the first substrate, the functional block, and the control circuit; and a first connector that is connected to the first substrate, wherein the first connector is configured to provide an electrical connection and a physical connection with the main storage module, and wherein in response to the extension storage module being attached to the main storage module, the storage device has a second form factor that is different from the first form factor.

According to example embodiments, a solid state drive (SSD) device comprising: a main module that has a first form factor; and an extension module that is configured to be electrically and physically attachable to and detachable from the main module, wherein the extension module comprises: a first substrate; an energy storage element on the first substrate, wherein the energy storage element is configured to provide an auxiliary power supply voltage to the main module; an energy management circuit on the first substrate, wherein the energy management circuit is configured to control the energy storage element; a first housing that extends around the first substrate, the energy storage element, and the energy management circuit; and a first connector that is connected to the first substrate, wherein the first connector is configured to provide an electrical connection and a physical connection with the main module, wherein the main module comprises: a second substrate; a storage controller on the second substrate; a plurality of nonvolatile memories on the second substrate, wherein the storage controller is configured to control the plurality of nonvolatile memories; a buffer memory on the second substrate, wherein the storage controller is configured to control the buffer memory; a second housing that extends around the second substrate, the storage controller, the plurality of nonvolatile memories, and the buffer memory; and a second connector that is connected to the second substrate, wherein the second connector is configured to provide an electrical connection and a physical connection with the extension module, wherein when the main module is electrically and physically connected to the extension module through the first connector and the second connector, the SSD device has a second form factor that is different from the first form factor, wherein the storage controller is configured to: read module information from the extension module, check the module information, determine a dump size for a data dump operation based on the module information, responsive to determining that a data dump event has occurred, transmit a power request signal to the energy management circuit based on at least one of a generation of a data dump command and a decrease in a voltage level of a main power supply voltage, receive the auxiliary power supply voltage from the energy storage element, and perform the data dump operation based on the auxiliary power supply voltage and the dump size, and wherein responsive to determining that the data dump event has occurred, and the data dump operation is performed, the storage controller is configured to move data from the buffer memory to the plurality of nonvolatile memories.

In the extension storage module, the storage device and the SSD device according to example embodiments, the main storage module having the first form factor may be changed to the storage device having the second form factor using the extension storage module. The connection between the extension storage module and the main storage module may be implemented without excessive design change. In addition, the extension storage module may provide at least one of various functions to the main storage module, such as providing the auxiliary power supply voltage to the main storage module or reducing the heat emitted from the main storage module. Accordingly, the form factor of the storage device may be efficiently changed using the extension storage module, additional function for the storage device may be efficiently provided, and it may be easily and flexibly responded to the customer's environments.

### BRIEF DESCRIPTION OF THE DRAWINGS

Illustrative, non-limiting example embodiments will be more clearly understood from the following detailed description taken in conjunction with the accompanying drawings.

FIG. 1 is a block diagram illustrating an extension storage module according to example embodiments.

FIG. 2 is a block diagram illustrating a main storage module according to example embodiments.

FIG. 3 is a diagram illustrating a storage device including an extension storage module and a main storage module according to example embodiments.

FIGS. 4A, 4B, 5A, and 5B are perspective views of an extension storage module, a main storage module, and a storage device.

FIG. 6 is a block diagram illustrating an extension storage module according to example embodiments.

FIG. 7 is a block diagram illustrating a main storage module according to example embodiments.

FIG. 8 is a diagram illustrating a storage device including an extension storage module and a main storage module according to example embodiments.

FIGS. 9A, 9B, 10A, and 10B are perspective views of an extension storage module, a main storage module, and a storage device.

FIG. 11 is a block diagram illustrating an extension storage module according to example embodiments.

FIG. 12 is a diagram illustrating a storage device including an extension storage module and a main storage module according to example embodiments.

FIG. 13 is a block diagram illustrating an extension storage module according to example embodiments.

FIG. 14 is a diagram illustrating a storage device including an extension storage module and a main storage module according to example embodiments.

FIGS. 15A and 15B are perspective views of an extension storage module, a main storage module, and a storage device.

FIG. 16 is a diagram illustrating a form factor of a storage device according to example embodiments.

FIGS. 17 and 18 are block diagrams illustrating operation of a storage device including an extension storage module and a main storage module according to example embodiments.

FIGS. 19, 20, 21, 22, 23, and 24 are flowcharts illustrating a method of operating a storage device according to example embodiments.

FIG. 25 is a block diagram illustrating an extension storage module according to example embodiments.

FIG. 26 is a block diagram illustrating a storage device and a storage system including the storage device according to example embodiments.

FIG. 27 is a block diagram illustrating a data center including a storage device according to example embodiments.

### DETAILED DESCRIPTION OF THE INVENTION

Enterprise and data center standard form factor (EDSFF), which is developed by storage networking industry association (SNIA), may define various form factors for SSDs. Some products may support various form factors depending on power, capacity, performance, hardware configuration, etc. of SSDs and/or depending on customer requests. However, products that support various form factors may have increased manufacturing burden.

Various example embodiments will be described more fully with reference to the accompanying drawings, in which embodiments are shown. The present disclosure may, however, be embodied in many different forms and should not be construed as limited to the embodiments set forth herein. Like reference numerals may refer to like elements throughout this application unless clearly described otherwise.

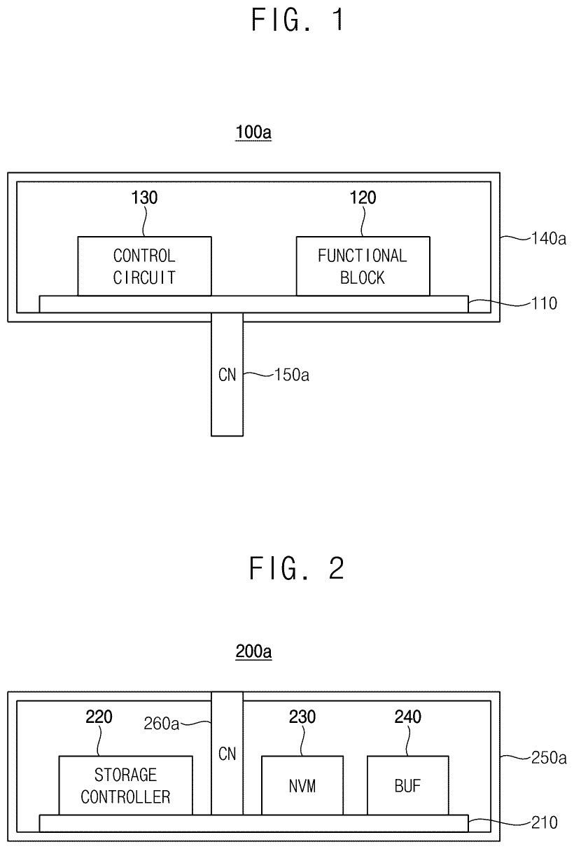

FIG. 1 is a block diagram illustrating an extension storage module according to example embodiments.

Referring to FIG. 1, an extension storage module 100a may include a substrate 110, a functional block 120, a control circuit 130, a housing (or case) 140a, and a connector (CN) 150a. The extension storage module 100a may simply be referred to as an extension module.

The substrate 110 may be a single-layered or multi-layered circuit substrate having an upper surface and a lower surface opposite to each other. For example, the substrate 110 may be a printed circuit board (PCB). The PCB may include wirings and vias connected (e.g., electrically connected) to the wirings. The wirings may include printed circuit patterns for interconnection with the electronic elements such as the functional block 120, the control circuit 130, and/or the connector 150a. It will be understood that when an element or layer is referred to as being “connected to”, or “coupled to” another element or layer, it may be directly on, connected to, or coupled to the other element or layer, or one or more intervening elements or layers may be present. In contrast, when an element is referred to as being “directly coupled,” “directly connected,” or “directly responsive” to, or “directly on,” another element, there are no intervening elements present. In addition, “electrical connection” conceptually includes a physical connection and a physical disconnection.

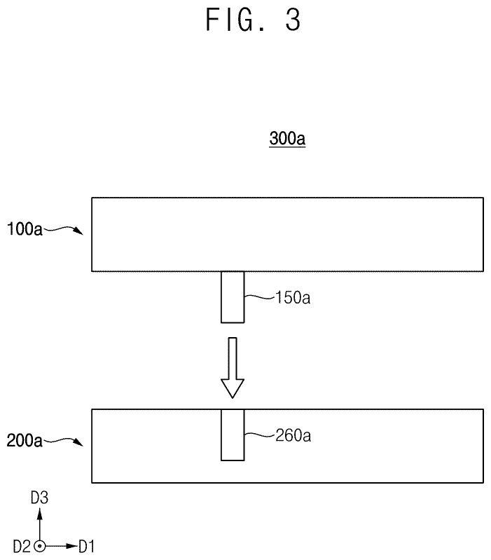

The functional block 120 may be mounted (or disposed) on the substrate 110 and may provide a first function for a main storage module (e.g., a main storage module 200a of FIG. 2). The control circuit 130 may be mounted (or disposed) on the substrate 110 and may control an operation of the functional block 120.

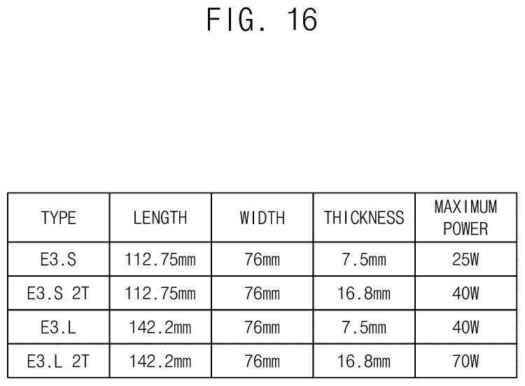

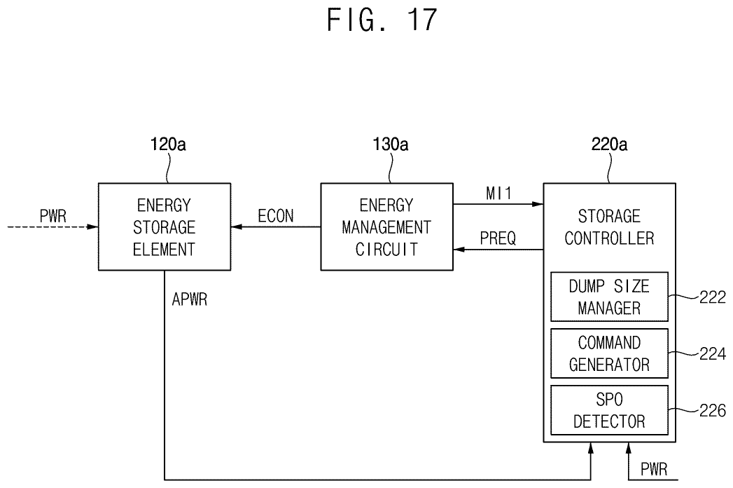

In some example embodiments, the functional block 120 may include an energy storage element (or means) that provides an auxiliary power supply voltage to the main storage module, and the control circuit 130 may include an energy management circuit that controls the energy storage element. In some example embodiments, the functional block 120 may include a cooling element (or means) for reducing heat emitted or generated from the main storage module, and the control circuit 130 may include a cooling control circuit that controls the cooling element. In other words, the cooling element may disperse the heat more efficiently and may lower the temperature of the main storage module. In some example embodiments, the functional block 120 may include both the energy storage element and the cooling element. Examples of the functional block 120 and the control circuit 130 will be described with reference to FIGS. 17 and 18.

However, example embodiments are not limited thereto, and the functional block 120 may include at least one of various elements and/or means that provide various functions to the main storage module.

The housing 140a may extend around (e.g., surround) the substrate 110, the functional block 120, and the control circuit 130. In other words, the substrate 110, the functional block 120, and the control circuit 130 may be fastened to (e.g., integrated in) the housing 140a, so that the functional block 120 and the control circuit 130 may be positioned fixedly within the housing 140a. For example, as illustrated in FIG. 1, the housing 140a may be formed integrally as a single case. For example, although not illustrated in FIG. 1, the housing 140a may include a lower case on which the substrate 110 is mounted, and an upper case coupled with the lower case to overlap (e.g., cover) the substrate 110, the functional block 120, and the control circuit 130 (in a third direction D3 (e.g., a Z-axis direction)). As used herein, “an element A overlapping an element B in a direction X” (or similar language) means that there is at least one line that extends in the direction X and intersects both the elements A and B.

In some example embodiments, the housing 140a may include, for example, a metal, a plastic (e.g., a polymer), a film, a material coated with epoxy, etc.

The connector 150a may be connected (e.g., electrically connected) to the substrate 110 and may be formed for electrical and/or physical connection with the main storage module. For example, the connector 150a may include a universal serial bus (USB) connector, board-to-board (B-to-B) connector, a PCB tab terminal, etc. Although FIG. 1 illustrates that the connector 150a is directly connected to the substrate 110, example embodiments are not limited thereto, and the extension storage module 100a may further include a connection part for electrically connecting the connector 150a with the substrate 110.

The extension storage module 100a may be electrically and physically attachable to and detachable from the main storage module through the connector 150a. When a combined (or coupled) module is obtained by attaching the extension storage module 100a to the main storage module, the combined module may have a predetermined form factor. In other words, a form factor of the main storage module may be changed using the extension storage module 100a. For example, although the extension storage module 100a itself does not satisfy a specific form factor, a configuration in which the extension storage module 100a and the main storage module are combined may satisfy a specific form factor.

A form factor may be a hardware design aspect that defines and prescribes the size, shape, and other physical specifications of components, particularly in electronics. The form factor may represent a broad class of similarly sized components, may prescribe a specific standard, and/or may define an entire system, as in a computer form factor. Standardization of form factors may be vital for hardware compatibility between different manufacturers.

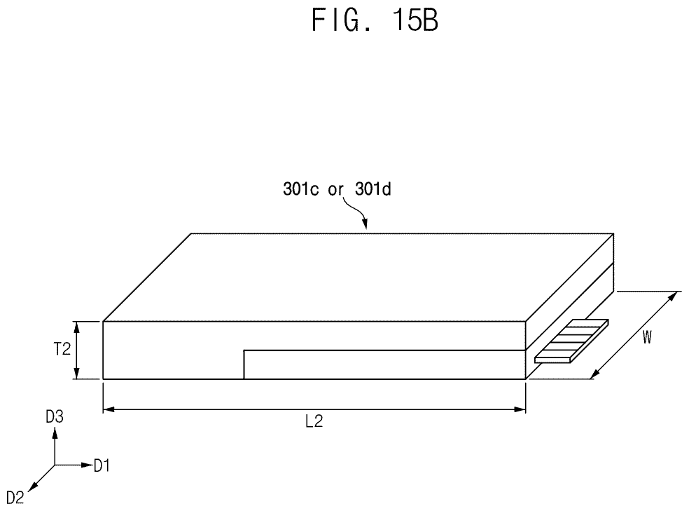

In some example embodiments, the predetermined form factor may correspond to one of a plurality form factors that are defined in enterprise and data center standard form factor (EDSFF) developed by storage networking industry association (SNIA), which will be described with reference to FIG. 16.

In some example embodiments, in a plan view or on a plane, the control circuit 130 may be disposed adjacent to the connector 150a on the upper surface of the substrate 110, and the functional block 120 may be disposed adjacent to the control circuit 130 on the upper surface of the substrate 110.

FIG. 2 is a block diagram illustrating a main storage module according to example embodiments.

Referring to FIG. 2, a main storage module 200a may include a substrate 210, a storage controller 220, a plurality of nonvolatile memories (NVM) 230, a buffer memory (BUF) 240, a housing 250a, and a connector 260a. The main storage module 200a may simply be referred to as a main module.

The substrate 210 may be a single-layered or multi-layered circuit substrate, for example, a PCB. The substrate 210 may be similar to the substrate 110 in FIG. 1.

In some example embodiments, the substrate 210 may extend in a first direction (e.g., a lengthwise direction). For example, the substrate 210 may have a rectangular or square shape, and may have a first side portion and a second side portion opposite to each other. For example, although not illustrated in FIG. 2, a host connector having connection terminals for connection with an external host device may be provided in the first side portion of the substrate 210. The main storage module 200a may be attached to or detached from the external host device through the host connector, and may be electrically connected to the external host device through the host connector. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

The storage controller 220 may be mounted (or disposed) on the substrate 210. The plurality of nonvolatile memories 230 and the buffer memory 240 may be mounted (or disposed) on the substrate 210 and may be controlled by the storage controller 220.

The storage controller 220 may control overall operations of the main storage module 200a and a storage device including the main storage module 200a and may communicate signals with the external host device using a host interface. For example, the signals communicated between the storage controller 220 and the external host device may include a command, an address, data, etc. The storage controller 220 may analyze and process the signals received from the external host device and may control the operation of the plurality of nonvolatile memories 230 based on the received command, address and data.

The plurality of nonvolatile memories 230 may be used as a storage medium of the main storage module 200a and the storage device including the main storage module 200a and may be connected (e.g., electrically connected) to the storage controller 220 through at least one channel. For example, the plurality of nonvolatile memories 230 may store various data, e.g., meta data, various user data, or the like.

The buffer memory 240 may store instructions and/or data that are executed and/or processed by the storage controller 220 and may temporarily store data stored in or to be stored into the plurality of nonvolatile memories 230.

The housing 250a may extend around (e.g., surround) the substrate 210, the storage controller 220, the plurality of nonvolatile memories 230, and the buffer memory 240. The housing 250a may be similar to the housing 140a in FIG. 1.

The connector 260a may be connected (e.g., electrically connected) to the substrate 210 and may be formed for electrical and/or physical connection with an extension storage module (e.g., the extension storage module 100a of FIG. 1). The connector 260a may be similar to the connector 150a in FIG. 1.

The main storage module 200a may have a first form factor that is predetermined. When a combined module is obtained by attaching the extension storage module (e.g., the extension storage module 100a of FIG. 1) to the main storage module 200a, the combined module may have a second form factor that is predetermined and different from the first form factor. In other words, the form factor of the main storage module 200a may be changed using the extension storage module. For example, the extension storage module may not have a predetermined form factor.

In some example embodiments, in a plan view or on a plane, the storage controller 220 may be disposed on the upper surface of the substrate 210 adjacent to the connector 260a and the host connector, and the plurality of nonvolatile memories 230 and the buffer memory 240 may be disposed adjacent to the storage controller 220 on the upper surface of the substrate 210.

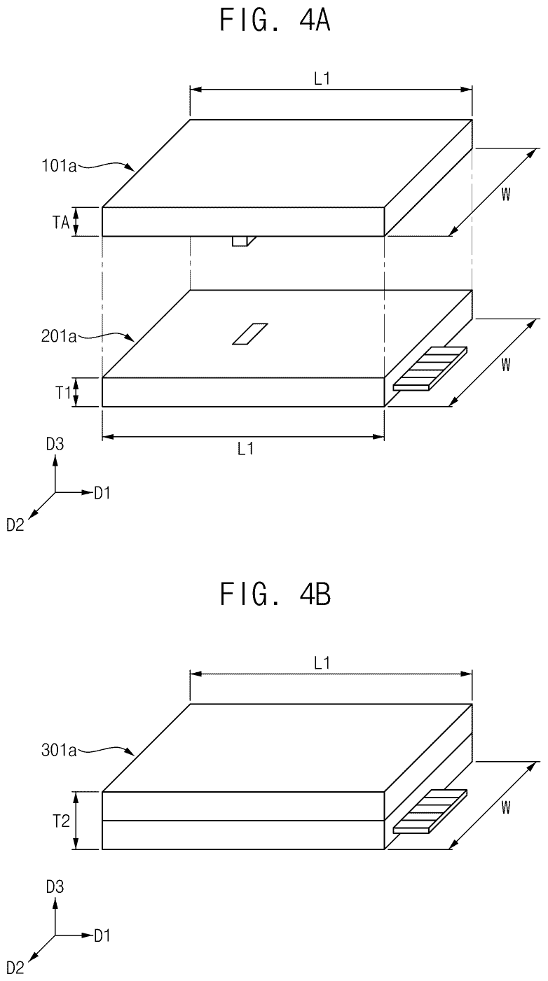

FIG. 3 is a diagram illustrating a storage device including an extension storage module and a main storage module according to example embodiments.

In FIG. 3, two directions that are each parallel or substantially parallel to a first surface (e.g., an upper surface) of a substrate (e.g., the substrate 110 in FIG. 1 and/or the substrate 210 in FIG. 2) and intersecting (e.g., crossing) each other are referred to as a first direction D1 (e.g., an X-axis direction) and a second direction D2 (e.g., a Y-axis direction). In addition, a direction vertical or substantially vertical to the first surface of the substrate is referred to as a third direction D3 (e.g., a Z-axis direction). For example, the first and second directions D1 and D2 may be perpendicular or substantially perpendicular to each other. In addition, the third direction D3 may be perpendicular or substantially perpendicular to both the first and second directions D1 and D2. Further, a direction indicated by an arrow in the figures and a reverse direction thereof are considered as the same direction. The definition of the first, second, and third directions D1, D2, and D3 are same in the subsequent figures.

Referring to FIG. 3, a storage device 300a may include an extension storage module 100a and a main storage module 200a.

In some example embodiments, the main storage module 200a and the storage device 300a including the main storage module 200a may be solid state drive (SSD) devices. For example, the main storage module 200a and the storage device 300a may be SSD devices used in a data center, a server, etc. that collects various data and provides various services or may be SSD devices for replacing a hard disk drive (HDD) device used in a personal computer (PC), a laptop, etc.

Hereinafter, example embodiments will be described based on an example where the main storage module 200a and the storage device 300a are SSD devices. However, example embodiments are not limited thereto, and the main storage module 200a and the storage device 300a may be one of a universal flash storage (UFS), a multimedia card (MMC), an embedded multimedia card (eMMC), a secure digital (SD) card, a micro SD card, a memory stick, a chip card, a universal serial bus (USB) card, a smart card, a compact flash (CF) card, or the like. In some embodiments, the main storage module 200a and the storage device 300a may be the same type or different types of storage devices.

For example, the extension storage module 100a and the main storage module 200a may be (substantially) the same as those described with reference to FIGS. 1 and 2, respectively.

The connector 150a included in the extension storage module 100a and the connector 260a included in the main storage module 200a may be directly connected to each other, and thus the extension storage module 100a and the main storage module 200a may be electrically and physically connected to each other.

In some example embodiments, the connector 260a may be a socket or may have a concave structure (or a groove structure), and the connector 150a may be a terminal or may have a protrusion structure corresponding to a shape of the connector 260a. For example, the connector 150a may be inserted into the connector 260a such that the extension storage module 100a is attached or coupled to the main storage module 200a, and the connector 150a may be removed from the connector 260a such that the extension storage module 100a is detached or separated from the main storage module 200a. For example, the connector 150a and the connector 260a may be referred to as a male connector and a female connector, respectively.

However, example embodiments are not limited thereto, and the connector 150a included in the extension storage module 100a may have a concave structure and the connector 260a included in the main storage module 200a may have a protrusion structure. In addition, each of the connectors 150a and 260a may be implemented in various other structures to facilitate the connection between the extension storage module 100a and the main storage module 200a.

In some example embodiments, each of the connectors 150a and 260a may include electrical pins or pads. For example, the extension storage module 100a and the main storage module 200a may exchange electrical signals such as voltage signals and/or current signals (e.g., a power supply voltage, control signals, etc.) through the connectors 150a and 260a. For example, the pins or pads may be contact pads or contact pins, but example embodiments are not limited thereto.

In some example embodiments, the extension storage module 100a and the housing 140a included therein may have a rectangular parallelepiped shape (or cuboid shape). Similarly, the main storage module 200a and the housing 250a included therein may have a rectangular parallelepiped shape. For example, each of the housing 140a and the housing 250a having the rectangular parallelepiped shape may include an upper surface, a lower surface and four side surfaces each of which has a rectangular shape. The upper surface and the lower surface may be parallel to each other, and the four side surfaces may meet the upper surface and the lower surface. Herein, when an element A is referred to as meeting with an element B, the element A may intersect with the element B. For example, the four side surfaces may intersect with the upper surface and the lower surface.

In some example embodiments, the connector 150a of the extension storage module 100a may be at least partially exposed (e.g., protruded) from one of the upper and lower surfaces of the housing 140a to the outside of the housing 140a. In some example embodiments, the connector 260a of the main storage module 200a may be formed from one of the upper and lower surfaces of the housing 250a to the inside of the housing 250a, and may be at least partially exposed (e.g., a portion of the concave structure may be exposed) to the outside of the housing 250a. For example, the connector 150a may extend outwardly from the housing 140a, and the connector 260a may extend inwardly from the housing 250a, or vice versa.

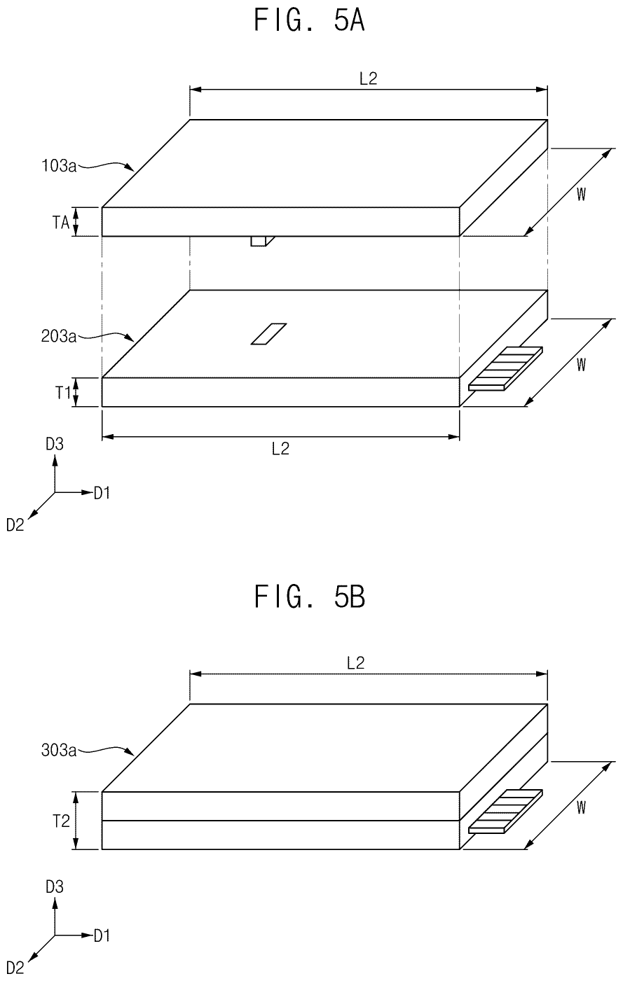

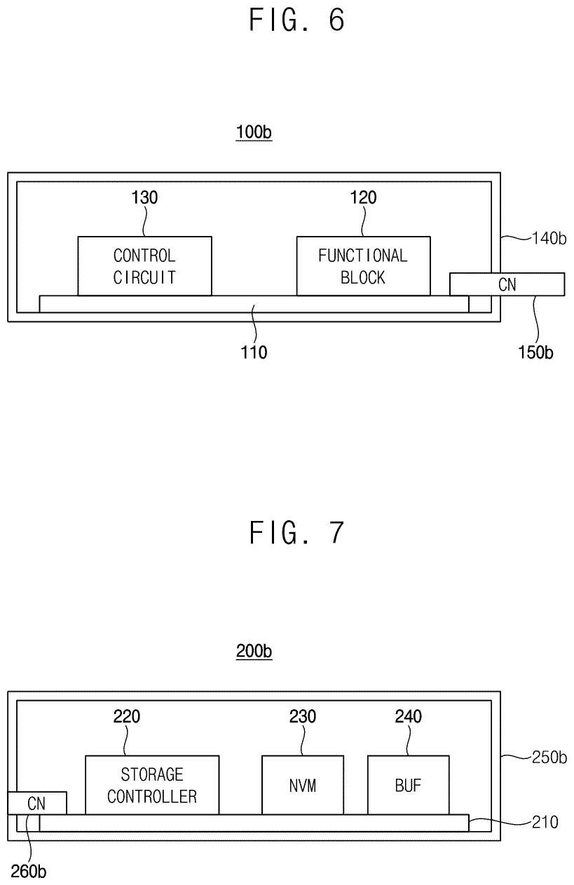

FIGS. 4A, 4B, 5A, and 5B are perspective views of an extension storage module, a main storage module, and a storage device.

Referring to FIGS. 4A and 4B, an example where an extension storage module 101a and a main storage module 201a are combined to form a storage device 301a is illustrated. The extension storage module 101a, the main storage module 201a, and the storage device 301a may correspond to the extension storage module 100a, the main storage module 200a, and the storage device 300a in FIGS. 1, 2, and 3, respectively.

The main storage module 201a (e.g., a housing of the main storage module 201a) may have a first length L1 (in the first direction D1), a first thickness T1 (in the third direction D3), and a first width W (in the second direction D2). In other words, a first form factor of the main storage module 201a may be defined by the first length L1, the first thickness T1, and the first width W. Hereinafter, the like references for lengths, thicknesses, and widths may refer to the like values of the lengths, thicknesses, and widths, not the same element. For example, the first length L1 of the extension storage module 101a and the first length L1 of the main storage module 201a may indicate the same value of lengths, not the same element.

The extension storage module 101a (e.g., a housing of the extension storage module 101a) may have the first length L1 (in the first direction D1), a thickness TA (in the third direction D3), and the first width W (in the second direction D2). For example, the thickness TA may be the same as or different from the first thickness T1.

The storage device 301a may be formed and/or implemented by attaching and/or combining the extension storage module 101a to the main storage module 201a. For example, a protrusion connector may be formed on a lower surface of the extension storage module 101a, and a concave connector may be formed on an upper surface of the main storage module 201a. For example, when the protrusion connector is inserted into the concave connector, the extension storage module 101a may be attached to the main storage module 201a such that the lower surface of the extension storage module 101a (e.g., a lower surface of the housing of the extension storage module 101a) and the upper surface of the main storage module 201a (e.g., an upper surface of the housing of the main storage module 201a) may be in contact with each other. However, example embodiments are not limited thereto, and one of the upper and lower surfaces of the extension storage module 101a (e.g., one of upper and lower surfaces of the housing of the extension storage module 101a) and one of the upper and lower surfaces of the main storage module 201a (e.g., one of upper and lower surfaces of the housing of the main storage module 201a) may be in contact with each other.

The storage device 301a, which is formed by attaching and/or combining the extension storage module 101a to the main storage module 201a, may have the first length L1 (in the first direction D1), a second thickness T2 (in the third direction D3), and the first width W (in the second direction D2). For example, the second thickness T2 may correspond to the sum of the first thickness T1 and the thickness TA (e.g., T2=T1+TA). In other words, a second form factor of the storage device 301a may be defined by the first length L1, the second thickness T2 and the first width W.

In some example embodiments, the main storage module 201a may have an E3.S form factor defined in EDSFF, and the storage device 301a may have an E3.S 2T form factor defined in EDSFF.

Referring to FIGS. 5A and 5B, an example where an extension storage module 103a and a main storage module 203a are combined to form a storage device 303a is illustrated. The descriptions repeated with or overlapping with descriptions of FIGS. 4A and 4B may be omitted in the interest of brevity. The extension storage module 103a, the main storage module 203a, and the storage device 303a may correspond to the extension storage module 100a, the main storage module 200a, and the storage device 300a in FIGS. 1, 2, and 3, respectively.

The main storage module 203a (e.g., a housing of the main storage module 203a) may have a second length L2 (in the first direction D1), the first thickness T1 (in the third direction D3), and the first width W (in the second direction D2). For example, the second length L2 may be longer than the first length L1 in FIG. 4A. A first form factor of the main storage module 203a may be defined by the second length L2, the first thickness T1, and the first width W.

The extension storage module 103a (e.g., a housing of the extension storage module 103a) may have the second length L2 (in the first direction D1), the thickness TA (in the third direction D3), and the first width W (in the second direction D2).

The storage device 303a, which may be formed by attaching and/or combining the extension storage module 103a to the main storage module 203a, may have the second length L2 (in the first direction D1), the second thickness T2 (in the third direction D3), and the first width W (in the second direction D2). In other words, a second form factor of the storage device 303a may be defined by the second length L2, the second thickness T2, and the first width W.

In some example embodiments, the main storage module 203a may have an E3.L form factor defined in EDSFF, and the storage device 303a may have an E3.L 2T form factor defined in EDSFF.

The extension storage modules 101a and 103a illustrated in FIGS. 4A, 4B, 5A and 5A may have the same length and the same width as the main storage modules 201a and 203a, respectively. The storage devices 301a and 303a, which are formed by attaching the extension storage modules 101a and 103a to the main storage modules 201a and 203a, respectively, may have the same length and the same width as the main storage modules 201a and 203a, respectively, and may be thicker than the main storage modules 201a and 203a, respectively. Therefore, the extension storage modules 101a and 103a may be referred to as thickness extension modules.

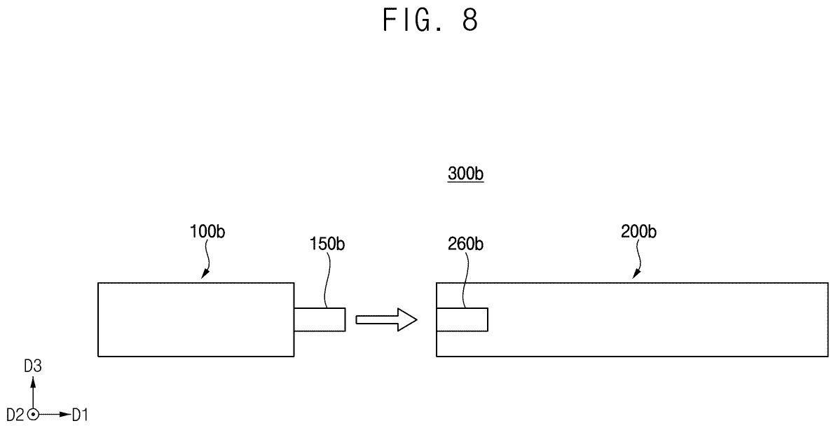

FIG. 6 is a block diagram illustrating an extension storage module according to example embodiments. The descriptions repeated with or overlapping with descriptions of FIG. 1 may be omitted in the interest of brevity.

Referring to FIG. 6, an extension storage module 100b may include a substrate 110, a functional block 120, a control circuit 130, a housing 140b, and a connector 150b.

The extension storage module 100b may be substantially the same as the extension storage module 100a of FIG. 1, except that a location of the connector 150b and a structure of the housing 140b are partially changed. For example, the connector 150b may extend outwardly (e.g., may protrude) from a side surface of the housing 140b. Descriptions of the substrate 110, the functional block 120, the control circuit 130, the housing 140b, and the connector 150b may be substantially the same as those described with reference to FIG. 1.

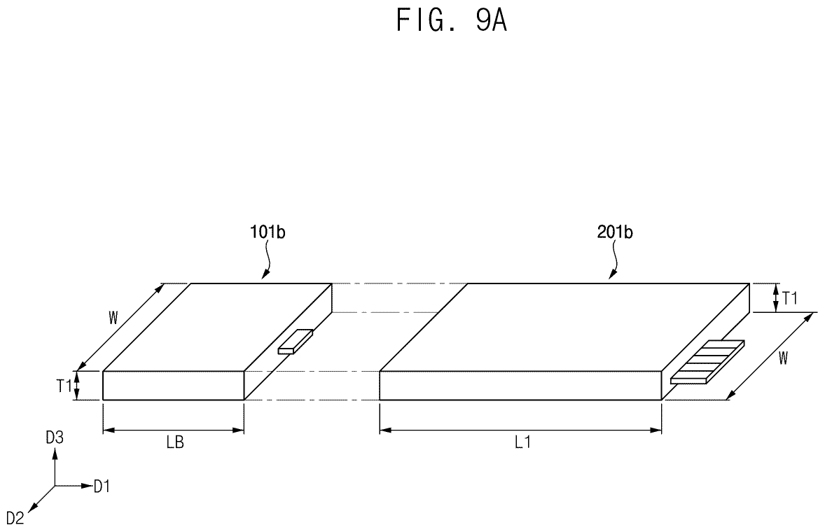

FIG. 7 is a block diagram illustrating a main storage module according to example embodiments. The descriptions repeated with or overlapping with descriptions of FIG. 2 may be omitted in the interest of brevity.

Referring to FIG. 7, a main storage module 200b may include a substrate 210, a storage controller 220, a plurality of nonvolatile memories 230, a buffer memory 240, a housing 250b, and a connector 260b.

The main storage module 200b may be substantially the same as the main storage module 200a of FIG. 2, except that a location of the connector 260b and a structure of the housing 250b are partially changed. For example, the connector 260b may extend inwardly from a side surface of the housing 250b. Descriptions of the substrate 210, the storage controller 220, the plurality of nonvolatile memories 230, the buffer memory 240, the housing 250b, and the connector 260b may be substantially the same as those described with reference to FIG. 2.

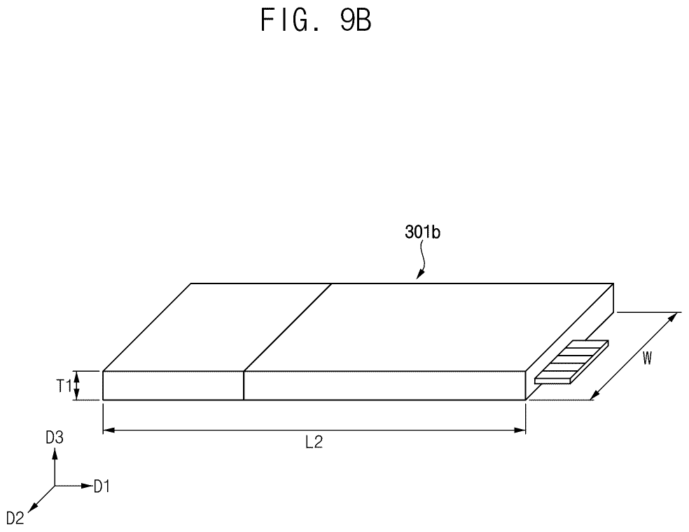

FIG. 8 is a diagram illustrating a storage device including an extension storage module and a main storage module according to example embodiments. The descriptions repeated with or overlapping with descriptions of FIG. 3 may be omitted in the interest of brevity.

Referring to FIG. 8, a storage device 300b may include an extension storage module 100b and a main storage module 200b.

The extension storage module 100b and the main storage module 200b may be substantially the same as those described with reference to FIGS. 6 and 7, respectively.

The connector 150b included in the extension storage module 100b and the connector 260b included in the main storage module 200b may be directly connected to each other, and thus the extension storage module 100b and the main storage module 200b may be electrically and physically connected to each other.

In some example embodiments, the extension storage module 100b and the housing 140b included therein may have a rectangular parallelepiped shape. Similarly, the main storage module 200b and the housing 250b included therein may have a rectangular parallelepiped shape.

In some example embodiments, the connector 150b of the extension storage module 100b may be at least partially exposed (e.g., protruded) from one of the four side surfaces of the housing 140b to the outside of the housing 140b. In some example embodiments, the connector 260b of the main storage module 200b may be formed from one of the four side surfaces of the housing 250b to the inside of the housing 250b, and may be at least partially exposed (e.g., a portion of the concave structure may be exposed) to the outside of the housing 250b.

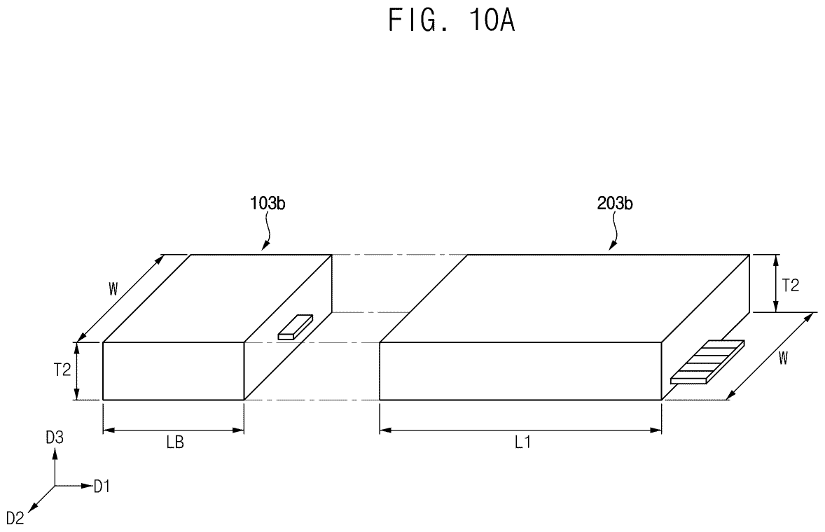

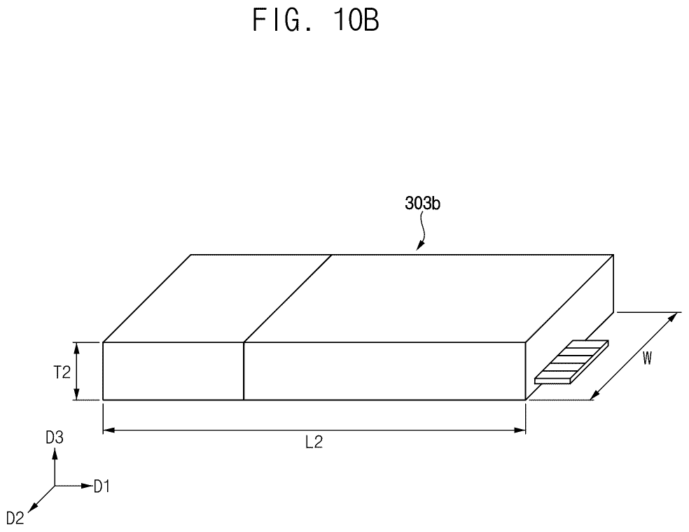

FIGS. 9A, 9B, 10A, and 10B are perspective views of an extension storage module, a main storage module, and a storage device. The descriptions repeated with or overlapping with descriptions of FIGS. 4A, 4B, 5A, and 5B may be omitted in the interest of brevity.

Referring to FIGS. 9A and 9B, an example where an extension storage module 101b and a main storage module 201b are combined to form a storage device 301b is illustrated. The extension storage module 101b, the main storage module 201b, and the storage device 301b may correspond to the extension storage module 100b, the main storage module 200b, and the storage device 300b in FIGS. 6, 7, and 8, respectively.

The main storage module 201b (e.g., a housing of the main storage module 201b) may have a first length L1 (in the first direction D1), a first thickness T1 (in the third direction D3) and a first width W (in the second direction D2). In other words, a first form factor of the main storage module 201b may be defined by the first length L1, the first thickness T1, and the first width W.

The extension storage module 101b (e.g., a housing of the extension storage module 101b) may have a length LB (in the first direction D1), the first thickness T1 (in the third direction D3) and the first width W (in the second direction D2). For example, the length LB may be different from the first length L1.

The storage device 301b may be formed and/or implemented by attaching and/or combining the extension storage module 101b to the main storage module 201b. For example, a protrusion connector may be formed on a right side surface (or front surface) of the extension storage module 101b, and a concave connector may be formed on a left side surface (or rear surface) of the main storage module 201b. For example, when the protrusion connector is inserted into the concave connector, the extension storage module 101b may be attached to the main storage module 201b such that the right side surface of the extension storage module 101b (e.g., a right side surface of the housing of the extension storage module 101b) and the left side surface of the main storage module 201b (e.g., a left side surface of the housing of the main storage module 201b) may be in contact with each other. However, example embodiments are not limited thereto, and one of the four side surfaces of the extension storage module 101b (e.g., one of four side surfaces of the housing of the extension storage module 101b) and one of the four side surfaces of the main storage module 201b (e.g., one of four side surfaces of the housing of the main storage module 201b) may be in contact with each other.

The storage device 301b, which is formed by attaching and/or combining the extension storage module 101b to the main storage module 201b, may have a second length L2 (in the first direction D1), the first thickness T1 (in the third direction D3), and the first width W (in the second direction D2). For example, the second length L2 may correspond to the sum of the first length L1 and the length LB (e.g., L2=L1+LB). In other words, a second form factor of the storage device 301b may be defined by the second length L2, the first thickness T1, and the first width W.

In some example embodiments, the main storage module 201b may have an E3.S form factor defined in EDSFF, and the storage device 301b may have an E3.L form factor defined in EDSFF.

Referring to FIGS. 10A and 10B, an example where an extension storage module 103b and a main storage module 203b are combined to form a storage device 303b is illustrated. The descriptions repeated with or overlapping with descriptions of FIGS. 9A and 9B may be omitted in the interest of brevity. The extension storage module 103b, the main storage module 203b, and the storage device 303b may correspond to the extension storage module 100b, the main storage module 200b, and the storage device 300b in FIGS. 6, 7, and 8, respectively.

The main storage module 203b (e.g., a housing of the main storage module 203b) may have the first length L1 (in the first direction D1), a second thickness T2 (in the third direction D3), and the first width W (in the second direction D2). For example, the second thickness T2 may be thicker than the first thickness T1 in FIG. 9A. In other words, a first form factor of the main storage module 203b may be defined by the first length L1, the second thickness T2, and the first width W

The extension storage module 103b (e.g., a housing of the extension storage module 103b) may have the length LB (in the first direction D1), the second thickness T2 (in the third direction D3), and the first width W (in the second direction D2).

The storage device 303b, which is formed by attaching and/or combining the extension storage module 103b to the main storage module 203b, may have the second length L2 (in the first direction D1), the second thickness T2 (in the third direction D3), and the first width W (in the second direction D2). In other words, the second form factor of the storage device 303b may be defined by the second length L2, the second thickness T2, and the first width W.

In some example embodiments, the main storage module 203b may have an E3.S 2T form factor defined in EDSFF, and the storage device 303b may have an E3.L 2T form factor defined in EDSFF.

The extension storage modules 101b and 103b illustrated in FIGS. 9A, 9B, 10A, and 10B may have the same thickness and the same width as the main storage modules 201b and 203b, respectively. The storage devices 301b and 303b, which are formed by attaching the extension storage modules 101b and 103b to the main storage modules 201b and 203b, respectively, may have the same thickness and the same width as the main storage modules 201b and 203b, respectively, and may be longer than the main storage modules 201b and 203b, respectively. Therefore, the extension storage modules 101b and 103b may be referred to as length extension modules.

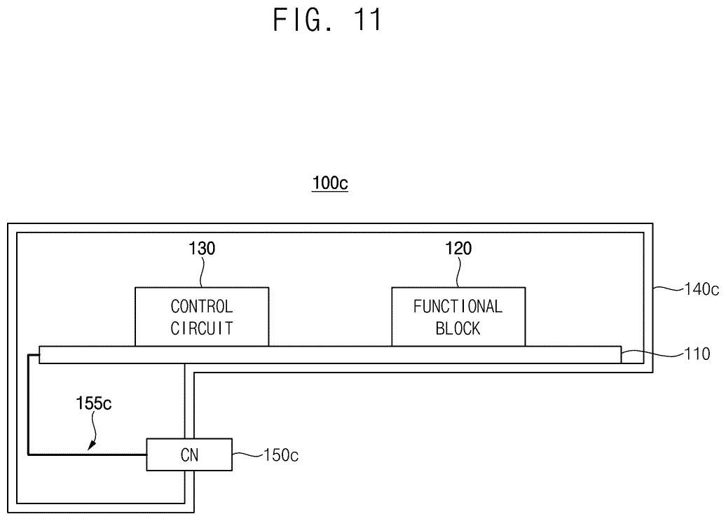

FIG. 11 is a block diagram illustrating an extension storage module according to example embodiments. The descriptions repeated with or overlapping with descriptions of FIG. 1 may be omitted in the interest of brevity.

Referring to FIG. 11, an extension storage module 100c may include a substrate 110, a functional block 120, a control circuit 130, a housing 140c, and a connector 150c. The extension storage module 100c may further include a connection part 155c.

The extension storage module 100c may be substantially the same as the extension storage module 100a of FIG. 1, except that the connection part 155c is further included, a location of the connector 150c and a structure and shape of the housing 140c are partially changed.

The connection part 155c may electrically connect the substrate 110 with the connector 150c. For example, the connection part 155c may include a cable, a PCB, and/or a flexible PCB (FPCB).

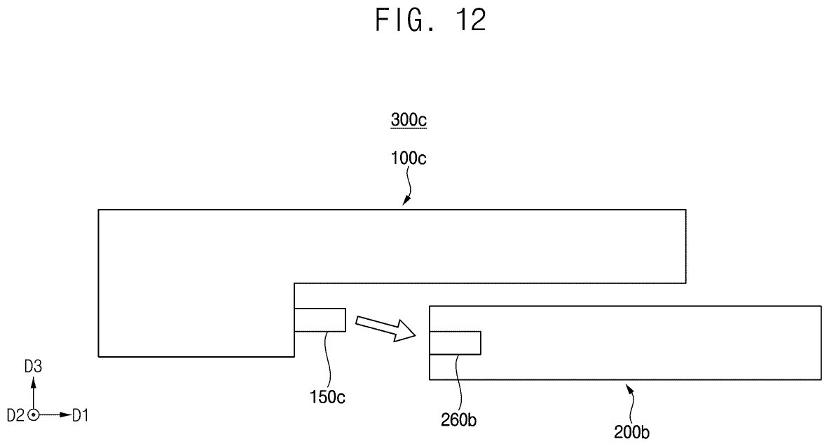

FIG. 12 is a diagram illustrating a storage device including an extension storage module and a main storage module according to example embodiments. The descriptions repeated with or overlapping with descriptions of FIG. 3 may be omitted in the interest of brevity.

Referring to FIG. 12, a storage device 300c may include an extension storage module 100c and a main storage module 200b.

The extension storage module 100c and the main storage module 200b may be substantially the same as those described above with reference to FIGS. 11 and 7, respectively.

The connector 150c included in the extension storage module 100c and the connector 260b included in the main storage module 200b may be directly connected to each other, and thus the extension storage module 100c and the main storage module 200b may be electrically and physically connected to each other.

In some example embodiments, the extension storage module 100c and the housing 140c included therein may have a two-step stair shape (e.g., an upside down shape of a two-step staircase). For example, the housing 140c having the two-step stair shape may include an upper surface, a middle surface, a lower surface, a first side surface, a second side surface, a third side surface, a fourth side surface and a fifth side surface. The upper surface, the middle surface, and the lower surface may be parallel to each other, and each of the upper surface, the middle surface, and the lower surface may have a rectangular shape. The first side surface and the second side surface may meet the upper surface, the middle surface, and the lower surface, the third side surface may meet the upper surface and the middle surface, the fourth side surface may meet the upper surface and the lower surface, and the fifth side surface meeting the middle surface and the lower surface.

In some example embodiments, the connector 150c of the extension storage module 100c may be at least partially exposed (e.g., protruded) from the fifth side surface of the housing 140c to the outside of the housing 140c.

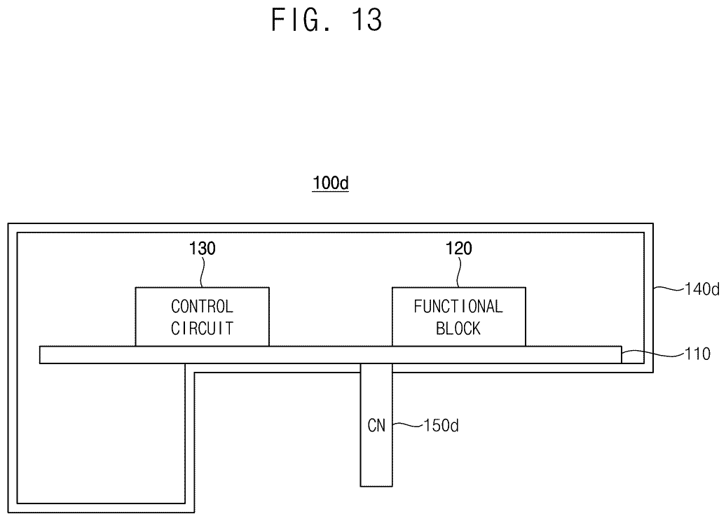

FIG. 13 is a block diagram illustrating an extension storage module according to example embodiments. The descriptions repeated with or overlapping with descriptions of FIGS. 1 and 11 may be omitted in the interest of brevity.

Referring to FIG. 13, an extension storage module 100d may include a substrate 110, a functional block 120, a control circuit 130, a housing 140d, and a connector 150d.

The extension storage module 100d may be substantially the same as the extension storage module 100a of FIG. 1, except that a location of the connector 150d, and a structure and shape of the housing 140d are partially changed.

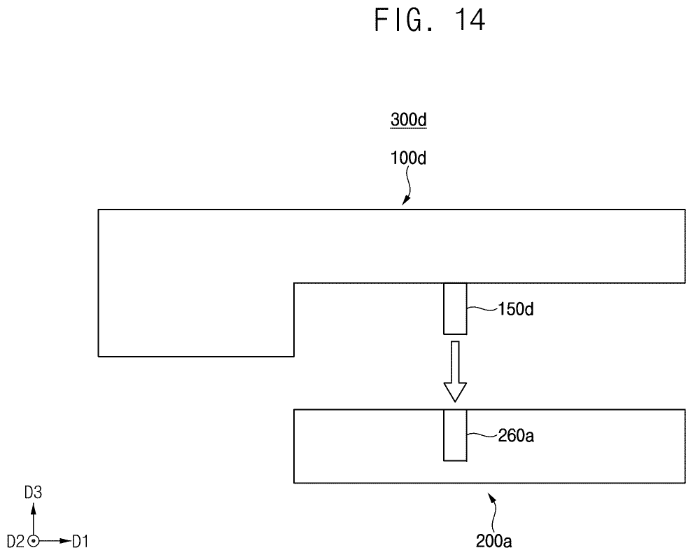

FIG. 14 is a diagram illustrating a storage device including an extension storage module and a main storage module according to example embodiments. The descriptions repeated with or overlapping with descriptions of FIGS. 3 and 12 may be omitted in the interest of brevity.

Referring to FIG. 14, a storage device 300d may include an extension storage module 100d and a main storage module 200a.

The extension storage module 100d and the main storage module 200a may be substantially the same as those described with reference to FIGS. 13 and 2, respectively.

The connector 150d included in the extension storage module 100d and the connector 260a included in the main storage module 200a may be directly connected to each other, and thus the extension storage module 100d and the main storage module 200a may be electrically and physically connected to each other.

In some example embodiments, the extension storage module 100d and the housing 140d included therein may have a two-step stair shape.

In some example embodiments, the connector 150d of the extension storage module 100d may be at least partially exposed (e.g., protruded) from the middle surface of the housing 140d to the outside of the housing 140d.

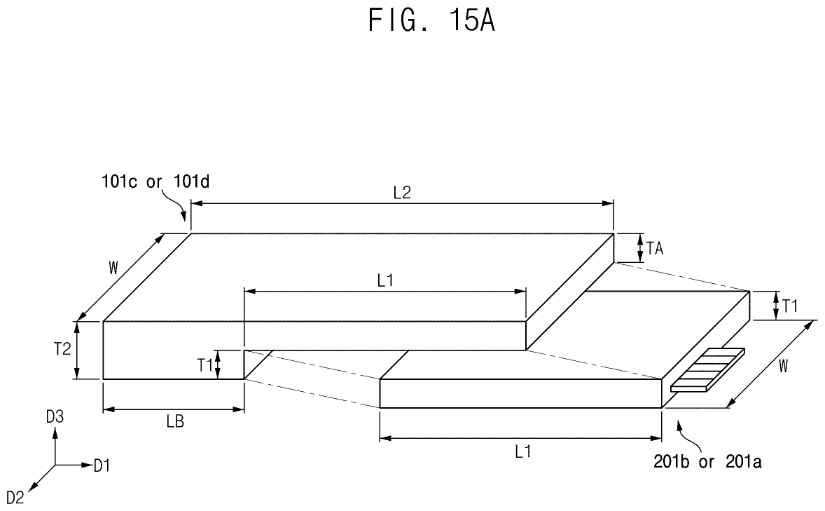

FIGS. 15A and 15B are perspective views of an extension storage module, a main storage module, and a storage device. The descriptions repeated with or overlapping with descriptions of FIGS. 4A, 4B, 5A, 5B, 9A, 9B, 10A, and 10B may be omitted in the interest of brevity.

Referring to FIGS. 15A and 15B, for example, the extension storage module 101c and the main storage module 201b may be combined to form the storage device 301c. In another example, the extension storage module 101d and the main storage module 201a may be combined to form the storage device 301d. The extension storage module 101c and the extension storage module 101d may correspond to the extension storage module 100c of FIG. 11 and the extension storage module 100d of FIG. 13, respectively. The main storage module 201b and the main storage module 201a may correspond to the main storage module 200b of FIG. 7 and the main storage module 200a of FIG. 2, respectively. The storage device 301c and the storage device 301d may correspond to the storage device 300c of FIG. 12 and the storage device 300d of FIG. 14, respectively.

As described above, the extension storage module 101c (or the extension storage module 101d) may have the two-step stair shape. For example, in the extension storage module 101c (or the extension storage module 101d) and a housing included therein, the upper surface may have a second length L2 (in the first direction D1) and a first width W (in the second direction D2), the middle surface may have a first length L1 (in the first direction D1) and the first width W, and the lower surface may have a length LB (in the first direction D1) and the first width W. For example, the extension storage module 101c (or the extension storage module 101d) and the housing included therein may have the first side surface that meets the upper surface and the lower surface and the second side surface that is symmetrical and opposite to the first side surface (in the second direction D2). For example, in the extension storage module 101c (or the extension storage module 101d) and the housing included therein, the third side surface may have a height corresponding to the thickness TA (in the third direction D3) and the first width W, the fourth side surface may have a height corresponding to the second thickness T2 (in the third direction D3) and the first width W, and the fifth side surface may have a height corresponding to the first thickness T1 (in the third direction D3) and the first width W.

In some embodiments, the storage device 301c may be formed and/or implemented by attaching and/or combining the extension storage module 101c to the main storage module 201b. For example, a protrusion connector may be formed on the fifth side surface of the extension storage module 101c, and a concave connector may be formed on a left side surface (or rear surface) of the main storage module 201b. For example, when the protrusion connector is inserted into the concave connector, the extension storage module 101c may be attached to the main storage module 201b such that the middle surface of the extension storage module 101c and the upper surface of the main storage module 201b are in contact with each other and the fifth side surface of the extension storage module 101c and the left side surface of the main storage module 201b are in contact with each other. In some embodiments, the storage device 301d may be formed and/or implemented by attaching and/or combining the extension storage module 101d to the main storage module 201a. For example, a protrusion connector may be formed on the middle surface of the extension storage module 101d, and a concave connector may be formed on the upper surface of the main storage module 201a. For example, when the protrusion connector is inserted into the concave connector, the extension storage module 101d may be attached to the main storage module 201a such that the middle surface of the extension storage module 101d and the upper surface of the main storage module 201a are in contact with each other and the fifth side surface of the extension storage module 101d and the left side surface of the main storage module 201a are in contact with each other.

Each of the storage device 301c, which is formed by attaching and/or combining the extension storage module 101c to the main storage module 201b, and the storage device 301d, which is formed by attaching and/or combining the extension storage module 101d to the main storage module 201a, may have the second length L2, the second thickness T2 and the first width W. In other words, a second form factor of the storage device 301c (or the storage device 301d) may be defined by the second length L2, the second thickness T2 and the first width W.

In some example embodiments, the main storage module 201b may have an E3.S form factor defined in EDSFF, and the storage device 301c may have an E3.L 2T form factor defined in EDSFF. In some example embodiments, the main storage module 201a may have an E3.S form factor defined in EDSFF, and the storage device 301d may have an E3.L 2T form factor defined in EDSFF.

The extension storage module 101c illustrated in FIGS. 15A and 15B may have the same width (in the second direction D2) as the main storage module 201b. The extension storage module 101d illustrated in FIGS. 15A and 15B may have the same width (in the second direction D2) as the main storage module 201a. The storage device 301c, which is formed by attaching the extension storage module 101c to the main storage module 201b, may have the same width (in the second direction D2) as the main storage module 201b, and may be longer (in the first direction D1) and thicker (in the third direction D3) than the main storage module 201b. Therefore, the extension storage module 101c may be referred to as a volume extension module. The storage device 301d, which is formed by attaching the extension storage module 101d to the main storage module 201a, may have the same width (in the second direction D2) as the main storage module 201a, and may be longer (in the first direction D1) and thicker (in the third direction D3) than the main storage module 201a. Therefore, the extension storage module 101d may be referred to as a volume extension module.

All of the main storage modules 201a, 203a, 201b and 203b, the extension storage modules 101a, 103a, 101b, 103b, 101c and 101d, and the storage devices 301a, 303a, 301b, 303b, 301c, and 301d may have the same width (in the second direction D2).

FIG. 16 is a diagram illustrating a form factor of a storage device according to example embodiments.

Referring to FIG. 16, the E3.S form factor, the E3.S 2T form factor, the E3.L form factor and the E3.L 2T form factor defined in EDSFF are illustrated. Such four form factors illustrated in FIG. 16 may have different lengths and different thicknesses, and may have the same width. In some example embodiments, the width may be referred to as a height, and the thickness may be defined as a width.

Factors for determining a form factor of a storage device may include power, capacity, performance, hardware configuration, etc. Among various elements included in a storage device, an element that occupies the largest volume in the hardware configuration may be an energy storage element. Even if a storage device with the same performance is developed, a storage device with the E3.S form factor that is the smallest form factor or the E3.L 2T form factor that is the largest form factor may be developed depending on the presence or absence of a power loss protection (PLP) function. Alternatively, the types of supported form factors may vary depending on the customer's request and/or specifications. Therefore, it may be required to develop and manufacture the storage devices with the same performance and various form factors, which may increase the burden of manufacturing processes and costs.

In the extension storage module and the storage device according to example embodiments, the form factor of the storage device may be changed using the extension storage module. For example, the extension storage module may be attached and/or combined to the main storage module having the first form factor, and thus the storage device having the second form factor may be formed. The connection between the extension storage module and the main storage module may be implemented with relatively simple design change by adding the connectors, without excessive design change. In addition, the extension storage module may provide at least one of various functions to the main storage module, such as providing the auxiliary power supply voltage to the main storage module or reducing the heat emitted from the main storage module. Accordingly, the form factor of the storage device may be efficiently changed using the extension storage module, additional function for the storage device may be efficiently provided, and it may be easily and flexibly responded to the customer's environments.

FIGS. 17 and 18 are block diagrams illustrating operation of an extension storage module and a storage device including the extension storage module according to example embodiments.

Referring to FIG. 17, an example of the functional block 120 and an example of the control circuit 130 that are included in the extension storage module (e.g., the extension storage module 100a in FIG. 1) are illustrated, and an example of a storage controller 220a included in the main storage module (e.g., the main storage module 200a in FIG. 2) is illustrated.

In some example embodiments, the functional block 120 may include an energy storage element 120a, and the control circuit 130 may include an energy management circuit 130a.

The energy storage element 120a may store energy based on a main power supply voltage PWR, and may provide an auxiliary power supply voltage APWR to the main storage module (e.g., to the storage controller 220a). For example, the energy storage element 120a may include a capacitor, a battery, a supercapacitor, etc. For example, capacitors that are capable of being included in the energy storage element 120a may be classified into electrolytic capacitors, film capacitors, tantalum capacitors, ceramic capacitors, etc., depending on dielectric material included therein. For example, the main power supply voltage PWR may be provided from the main storage module.

When the extension storage module is attached to the main storage module, the energy management circuit 130a may provide module information MI1 to the main storage module (e.g., to the storage controller 220a). When a power request signal PREQ is received from the main storage module (e.g., from the storage controller 220a), the energy management circuit 130a may control the energy storage element 120a by generating a control signal ECON for controlling the energy storage element 120a such that and the auxiliary power supply voltage APWR is provided to the main storage module (e.g., to the storage controller 220a).

In addition, the energy management circuit 130a may manage operations of charging and discharging of the energy storage element 120a, may monitor an operation and a lifetime of the energy storage element 120a, and/or may inform the main storage module (e.g., the storage controller 220a) that the provision of the auxiliary power supply voltage APWR is impossible when a defect or failure occurs in the energy storage element 120a.

When the extension storage module is attached to the main storage module, the storage controller 220a may read the module information MI1 from the extension storage module (e.g., from the energy management circuit 130a), and may check or identify the module information MI1.

When it is checked based on the module information MI1 that the extension storage module includes the energy storage element 120a and the energy management circuit 130a, the storage controller 220a may determine a dump size for a data dump operation, which is performed when a data dump event occurs, based on the module information MI1. For example, the storage controller 220a may include a dump size manager 222 that determines the dump size.

The data dump operation may represent or indicate an operation that normally terminates the operation of the storage device based on the auxiliary power supply voltage APWR. The data dump operation may be referred to as a PLP operation or a PLP dump operation. For example, during the data dump operation, the storage device may temporarily operate based on the auxiliary power supply voltage APWR, and a reset operation and/or a flush operation in which data is transferred from the buffer memory (e.g., the buffer memory 240 of FIG. 2) to the plurality of nonvolatile memories (e.g., the plurality of nonvolatile memories 230) may be performed based on the auxiliary power supply voltage APWR before the provision of the auxiliary power supply voltage APWR is blocked. The dump size may represent or indicate a size of data to be moved from the buffer memory 240 to the plurality of nonvolatile memories 230.

When the data dump event occurs, the storage controller 220a may generate the power request signal PREQ. For example, the storage controller 220a may include a command generator 224 and a sudden power off (SPO) detector 226 that generate and/or detect the data dump event.

In some example embodiments, the data dump event may occur based on a data dump command generated from the storage controller 220a. For example, the command generator 224 may generate the data dump command, and the storage controller 220a may generate the power request signal PREQ based on the data dump command.

In some example embodiments, the data dump event may occur based on a state of the main power supply voltage PWR monitored by the storage controller 220a. For example, the SPO detector 226 may monitor the main power supply voltage PWR. For example, in a SPO condition (or situation) in which the main power supply voltage PWR is suddenly (e.g., accidently) turned off, e.g., when a voltage level of a main power supply voltage PWR becomes lower than a reference voltage level, the storage controller 220a may generate the power request signal PREQ

When the data dump event occurs, the storage controller 220a may generate the power request signal PREQ, may receive the auxiliary power supply voltage APWR from the energy storage element 120a, and may perform the data dump operation based on the auxiliary power supply voltage APWR and the dump size determined by the dump size manager 222.

Although not illustrated in FIG. 17, the main power supply voltage PWR may be provided from the external host device to all components of the main storage module and the extension storage module, and the auxiliary power supply voltage APWR may be provided to all components of the main storage module. When the data dump operation is completed, the storage controller 220a may generate a request to stop providing the auxiliary power supply voltage APWR.

Referring to FIG. 18, an example of the functional block 120 and an example of the control circuit 130 that are included in the extension storage module (e.g., the extension storage module 100a in FIG. 1) are illustrated, and an example of a storage controller 220b included in the main storage module (e.g., the main storage module 200a in FIG. 2) is illustrated.

In some example embodiments, the functional block 120 may include a cooling element 120b, and the control circuit 130 may include a cooling control circuit 130b.

The cooling element 120b may provide a cooling function CLF to reduce heat (e.g., to control an operating temperature) emitted or generated from the main storage module (e.g., from the storage controller 220b). For example, the cooling element 120b may include a fan providing forced air, a water-cooled cooler providing cold water, a thermoelectric cooler (TEC), etc.

When the extension storage module is attached to the main storage module, the cooling control circuit 130b may provide module information MI2 to the main storage module (e.g., to the storage controller 220b). When a cooling request signal CREQ is received from the main storage module (e.g., from the storage controller 220b), the cooling control circuit 130b may control the cooling element 120b by generating a control signal CCON for controlling the cooling element 120b such that the operating temperature of the main storage module (e.g., of the storage controller 220b) is reduced (such that the cooling function CLF is provided to the main storage module (e.g., to the storage controller 220b)). For example, the cooling control circuit 130b may include a power management integrated circuit (PMIC), a micro-controller unit (MCU), etc.

When the extension storage module is attached to the main storage module, the storage controller 220b may read the module information MI2 from the extension storage module (e.g., from the cooling control circuit 130b), and may check or identify the module information MI2.

When it is checked based on the module information MI2 that the extension storage module includes the cooling element 120b and the cooling control circuit 130b, the storage controller 220b may monitor the operating temperature, and may generate the cooling request signal CREQ. For example, the storage controller 220b may include a temperature sensor 228 that measures the operating temperature.

When the operating temperature becomes higher than a reference temperature, the storage controller 220b may generate the cooling request signal CREQ and may receive the cooling function CLF from the cooling element 120b.

Although not illustrated in FIG. 18, when the operating temperature becomes lower than a second reference temperature by the cooling function CLF, the storage controller 220b may generate a request to stop providing the cooling function CLF.

In some example embodiments, the functional block 120, the control circuit 130 and the storage controller 220 may be implemented by combining the examples of FIGS. 17 and 18.

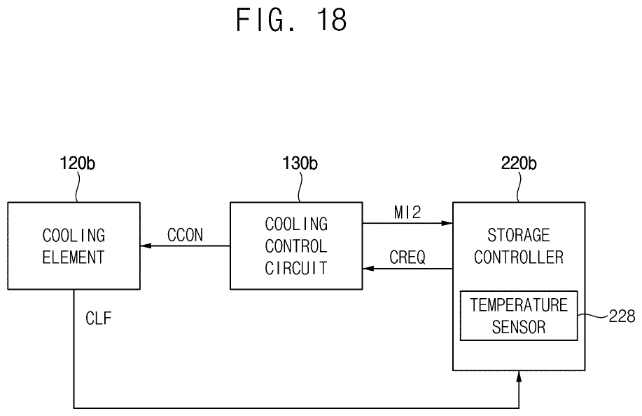

FIGS. 19, 20, 21, 22, 23, and 24 are flowcharts illustrating a method of operating a storage device according to example embodiments.

Referring to FIG. 19, in a method of operating a storage device according to example embodiments, the extension storage module is combined with the main storage module (operation S100). For example, as described with reference to FIGS. 1 through 16, the extension storage module and the main storage module may be combined by the connectors in various manners, and thus the form factor of the storage device may be changed.

The storage controller included in the main storage module may read the module information from the extension storage module and checks the module information (operation S200). The storage controller may control the operation of the extension storage module based on the module information (operation S300). For example, based on the module information, the functions provided by the extension storage module may be identified, and the appropriate control operations may be performed.

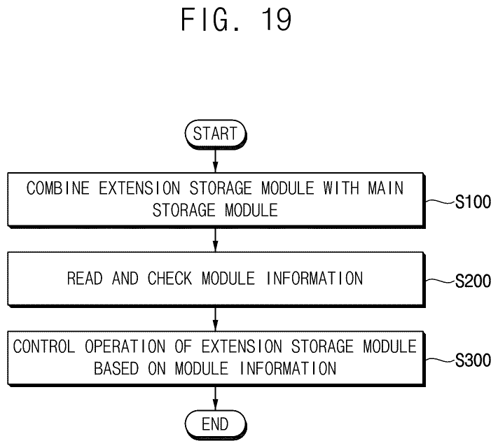

Referring to FIGS. 17 and 20, an example where the auxiliary power supply voltage APWR is provided from the extension storage module in operation S300 of FIG. 19 is illustrated.

For example, the storage controller 220a may determine the dump size for the data dump operation based on the module information MI1 (operation S410). When the data dump event occurs (operation S420: YES), the storage controller 220a may transmit the power request signal PREQ to the energy management circuit 130a (operation S430), may receive the auxiliary power supply voltage APWR provided from the energy storage element 120a under the control of the energy management circuit 130a (operation S440), and may perform the data dump operation based on the auxiliary power supply voltage APWR and the dump size (operation S450).

When the data dump event does not occur (operation S420: NO), the storage controller 220a may wait for occurring of the data dump event (operation S425), or may perform at least one of various normal operations of the storage device.

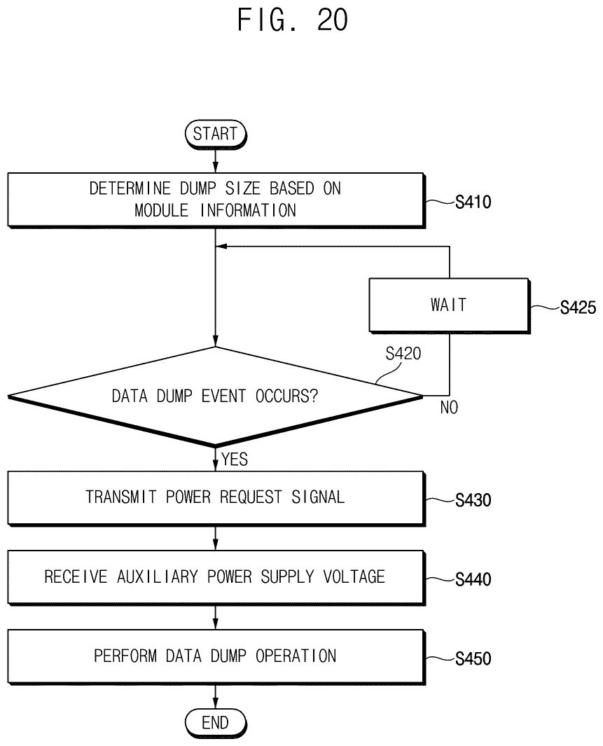

Referring to FIGS. 17 and 21, an example where the occurrence of the data dump event is checked based on the data dump command in operation S420 of FIG. 20 is illustrated.

When the command generator 224 generates the data dump command (operation S422: YES), the storage controller 220a may determine that the data dump event occurs (operation S424), and may perform operations S430, S440, and S450. When the command generator 224 does not generate the data dump command (operation S422: NO), the storage controller 220a may determine that the data dump event does not occur (operation S426), and may perform operation S425.

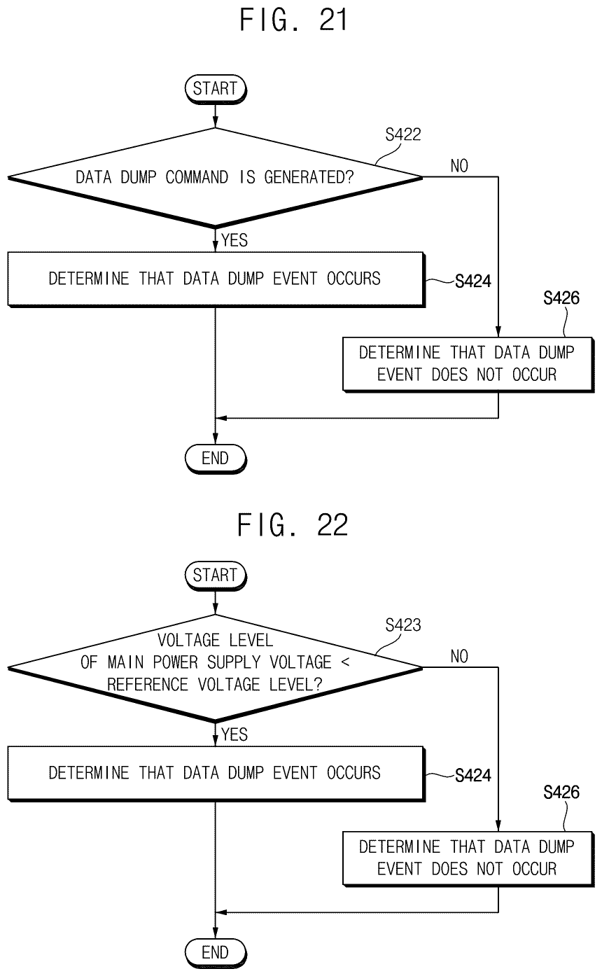

Referring to FIGS. 17 and 22, an example where the occurrence of the data dump event is checked based on monitoring of the main power supply voltage PWR using the SPO detector 226 in operation S420 of FIG. 20 is illustrated.

When it is detected by monitoring the main power supply voltage PWR that the voltage level of the main power supply voltage PWR becomes lower than the reference voltage level (operation S423: YES), the storage controller 220a may determine that the data dump event occurs (operation S424), and may perform operations S430, S440, and S450. When the voltage level of the main power supply voltage PWR is higher than or equal to the reference voltage level (operation S423: NO), the storage controller 220a may determine that the data dump event does not occur (operation S426), and may perform operation S425.

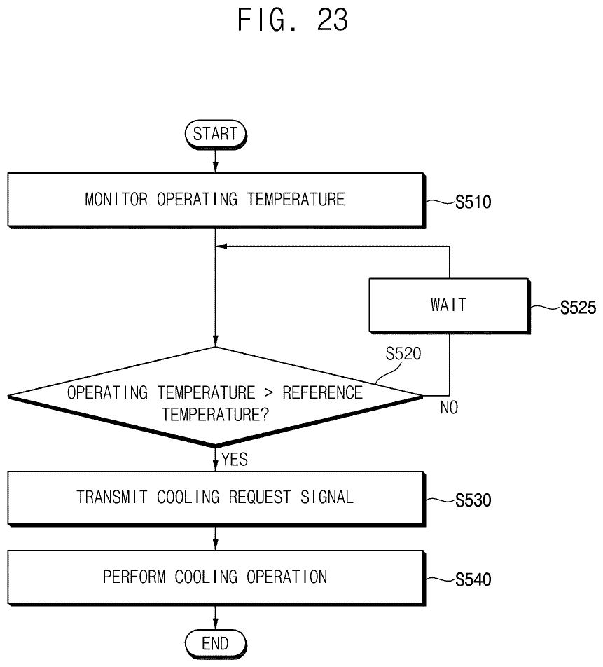

Referring to FIGS. 18 and 23, an example where the cooling function CLF is provided from the extension storage module in operation S300 of FIG. 19 is illustrated.

For example, the storage controller 220b may check or monitor the operating temperature using the temperature sensor 228 (operation S510). When the operating temperature becomes higher than the reference temperature (operation S520: YES), the storage controller 220b may transmit the cooling request signal CREQ to the cooling control circuit 130b (operation S530), and may perform the cooling operation based on the cooling function CLF provided from the cooling element 120b under the control of the cooling control circuit 130b (operation S540).

When the operating temperature is lower than or equal to the reference temperature (operation S520: NO), the storage controller 220b may wait for increasing the operating temperature (operation S525) or may perform at least one of various normal operations of the storage device.

For example, when the operating temperature becomes lower than the second reference temperature by the cooling operation, the storage controller 220b may generate a request to stop the cooling operation (e.g., stop the operation of the cooling element 120b).

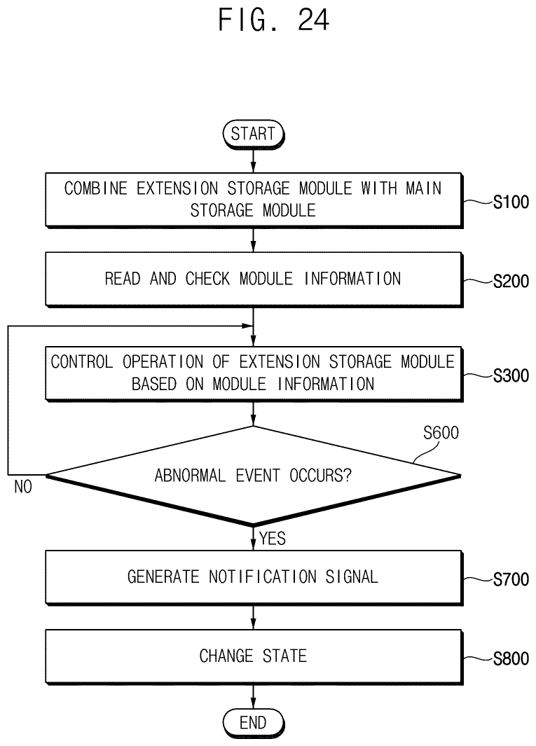

Referring to FIG. 24, in a method of operating a storage device according to example embodiments, operations S100, S200, and S300 may be substantially the same as those described with reference to FIG. 19.

When an abnormal event occurs for the extension storage module (operation S600: YES), the storage controller may generate a notification signal (operation S700), and may change the state of the storage device (operation S800).

In some example embodiments, the abnormal event may represent a situation where an operation abnormality, defect, failure, etc. of the extension storage module is detected. For example, when the extension storage module includes the energy storage element 120a, the abnormal event may represent a case in which the energy storage element 120a does not operate normally because the lifetime of the energy storage element 120a is over and/or the defect or failure such as open circuit, short circuit, etc. occurs in the energy storage element 120a. For example, when the extension storage module includes the cooling element 120b, the abnormal event may represent a case in which the operating temperature is not reduced even when the cooling element 120b is driven because the cooling element 120b does not operate normally.

In some example embodiments, the state change may represent an operation of replacing the extension storage module. For example, a replacement operation may be performed by detaching the defective extension storage module from the main storage module and by attaching a normal extension storage module to the main storage module.

In some example embodiments, the state change may represent an operation of handling or treating the extension storage module into an unusable state. For example, an operation mode of the extension storage module may be changed so as not to use the function of the extension storage module while maintaining the connection of the extension storage module.

When the abnormal event does not occur (operation S600: NO), operation S300 may be continued or may be performed repeatedly.

Conventionally, the functional block 120 was formed to be integrated into the storage device (e.g., mounted on the substrate 210), and there was a problem in that it was difficult to replace or change the functional block 120. In addition, there was a problem in that the lifetime of the functional block 120 was shortened due to heat generation from the controller chip, memory chip, etc.

In the storage device according to example embodiments, the functional block 120 may be included in the extension storage module that is formed separately from the main storage module. Accordingly, the possibility of defects or failures may be reduced, and the operation of replacing or changing the functional block 120 may be relatively easily performed.

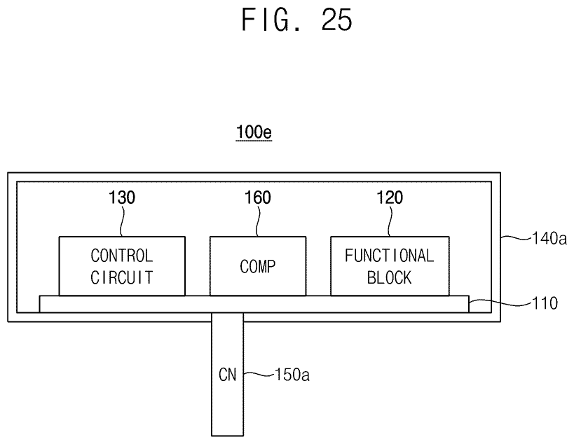

FIG. 25 is a block diagram illustrating an extension storage module according to example embodiments. The descriptions repeated with or overlapping with descriptions of FIG. 1 will be omitted in the interest of brevity.

Referring to FIG. 25, an extension storage module 100e may include a substrate 110, a functional block 120, a control circuit 130, a housing 140a, and a connector 150a. The extension storage module 100e may further include a compensation circuit (COMP) 160.

The extension storage module 100e may be substantially the same as the extension storage module 100a of FIG. 1, except that the extension storage module 100e further includes the compensation circuit 160.

When the extension storage module 100e and the main storage module 200a are connected to each other through the connectors 150a and 260a, the compensation circuit 160 may correct or compensate signal distortion (e.g., signal integrity (SI) distortion) caused by the connectors 150a and 260a.

Although not illustrated in detail, each of the extension storage modules 100b, 100c, and 100d of FIGS. 6, 11 and 13 may further include the compensation circuit 160.

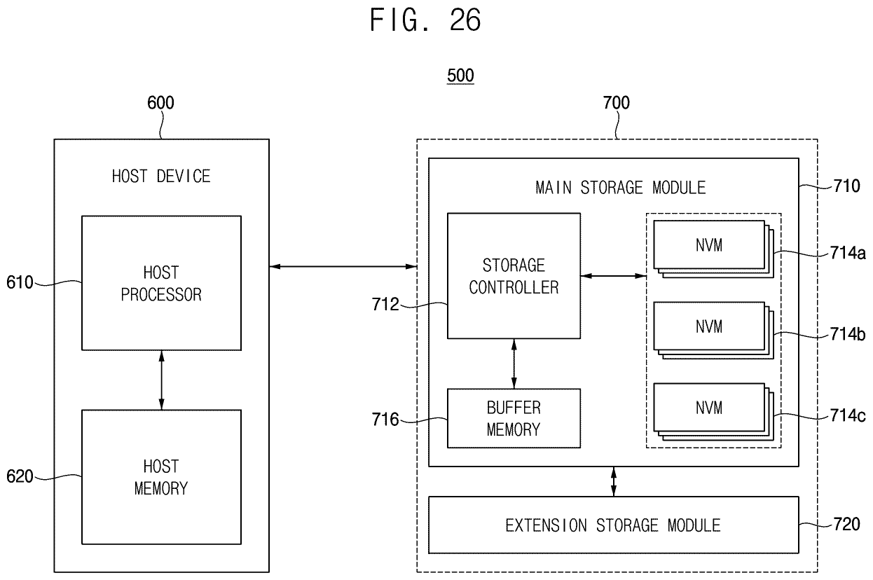

FIG. 26 is a block diagram illustrating a storage device and a storage system including the storage device according to example embodiments.

Referring to FIG. 26, a storage system 500 may include a host device 600 and a storage device 700.

The host device 600 may control overall operations of the storage system 500. The host device 600 may include a host processor 610 and a host memory 620.

The host processor 610 may control an operation of the host device 600. For example, the host processor 610 may execute an operating system (OS). For example, the operating system may include a file system for file management and a device driver for controlling peripheral devices including the storage device 700 at the operating system level. The host memory 620 may store instructions and/or data that are executed and/or processed by the host processor 610.

The storage device 700 may be accessed by the host device 600. The storage device 700 may include a main storage module 710 and an extension storage module 720.

The main storage module 710 may include a storage controller 712, a plurality of nonvolatile memories 714a, 714b, and 714c, and a buffer memory 716.

The storage controller 712 may control an operation of the storage device 700. For example, the storage controller 712 may control operations of the main storage module 710 and the extension storage module 720 based on a request and data that are received from the host device 600.

The plurality of nonvolatile memories 714a, 714b, and 714c may be controlled by the storage controller 712 and may store a plurality of data. For example, the plurality of nonvolatile memories 714a, 714b, and 714c may store the meta data, various user data, or the like.

In some example embodiments, each of the plurality of nonvolatile memories 714a, 714b, and 714c may include a NAND flash memory. In some example embodiments, each of the plurality of nonvolatile memories 714a, 714b, and 714c may include, for example, an electrically erasable programmable read only memory (EEPROM), a phase-change random access memory (PRAM), a resistive random access memory (RRAM), a nano floating gate memory (NFGM), a polymer random access memory (PoRAM), a magnetic random access memory (MRAM), a ferroelectric random access memory (FRAM), and/or the like.

The buffer memory 716 may store instructions and/or data that are executed and/or processed by the storage controller 712 and may temporarily store data stored in or to be stored into the plurality of nonvolatile memories 714a, 714b, and 714c. For example, the buffer memory 716 may include at least one of various volatile memories, e.g., a static random access memory (SRAM), a dynamic random access memory (DRAM), or the like.

The extension storage module 720 and the storage device 700 may be the extension storage module and the storage device according to example embodiments, and may perform the operations with the structure described with reference to FIGS. 1 through 25. When the extension storage module 720 is attached to the main storage module 710, the main storage module 710 having the first form factor may be changed to the storage device 700 having the second form factor (by being physically and electrically connected to the extension storage module 720). In addition, the extension storage module 720 may provide various functions to the main storage module 710, such as providing the auxiliary power supply voltage to the main storage module 710 and/or reducing heat emitted from the main storage module 710.

In some example embodiments, the storage device 700 may be connected (e.g., electrically connected) to the host device 600 via a block accessible interface which may include, for example, a UFS, an eMMC, a nonvolatile memory express (NVMe) bus, a serial advanced technology attachment (SATA) bus, a small computer small interface (SCSI) bus, a serial attached SCSI (SAS) bus, or the like. The storage device 700 may use a block accessible address space corresponding to an access size of the plurality of nonvolatile memories 714a, 714b, and 714c to provide the block accessible interface to the host device 600, for allowing the access by units of a memory block with respect to data stored in the plurality of nonvolatile memories 714a, 714b, and 714c.

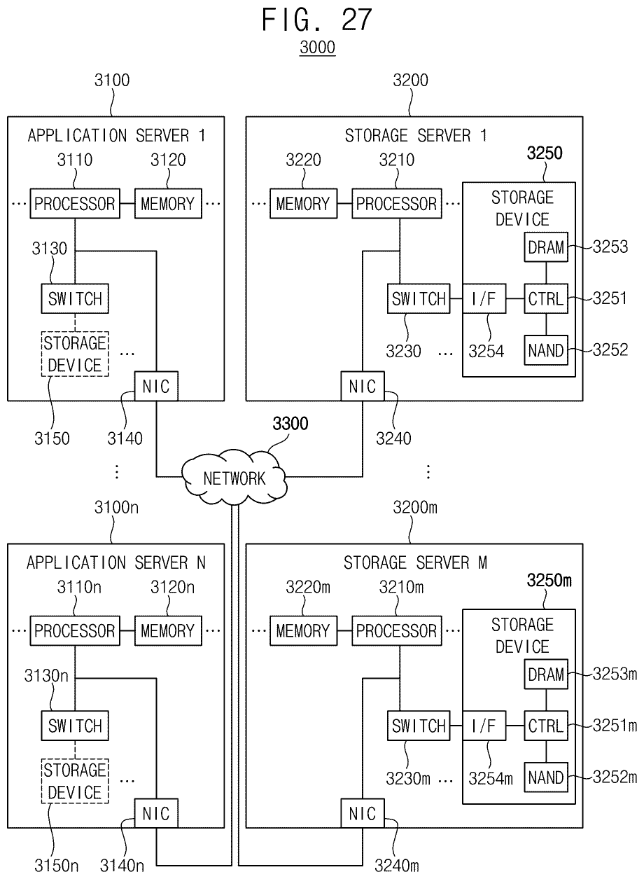

FIG. 27 is a block diagram illustrating a data center including a storage device according to example embodiments.

Referring to FIG. 27, a data center 3000 may be a facility that collects various types of data and provides various services, and may be referred to as a data storage center. The data center 3000 may be a system for operating search engines and databases, and may be a computing system used by companies such as banks or government agencies. The data center 3000 may include application servers 3100 to 3100n and storage servers 3200 to 3200m. The number of the application servers 3100 to 3100n and the number of the storage servers 3200 to 3200m may be variously selected according to example embodiments, and the number of the application servers 3100 to 3100n and the number of the storage servers 3200 to 3200m may be different from each other.

The application server 3100 may include at least one processor 3110 and at least one memory 3120, and the storage server 3200 may include at least one processor 3210 and at least one memory 3220. An operation of the storage server 3200 will be described as an example. The processor 3210 may control overall operations of the storage server 3200, and may access the memory 3220 to execute instructions and/or data loaded in the memory 3220. The memory 3220 may include, for example, a double data rate (DDR) synchronous dynamic random access memory (SDRAM), a high bandwidth memory (HBM), a hybrid memory cube (HMC), a dual in-line memory module (DIMM), an Optane DIMM, a nonvolatile DIMM (NVDIMM), etc. The number of the processors 3210 and the number of the memories 3220 included in the storage server 3200 may be variously selected according to example embodiments. In some example embodiments, the processor 3210 and the memory 3220 may provide a processor-memory pair. In some example embodiments, the number of the processors 3210 and the number of the memories 3220 may be different from each other. The processor 3210 may include a single core processor or a multiple core processor. The above description of the storage server 3200 may be similarly applied to the application server 3100. The application server 3100 may include at least one storage device 3150, and the storage server 3200 may include at least one storage device 3250. In some example embodiments, the application server 3100 may not include the storage device 3150. The number of the storage devices 3250 included in the storage server 3200 may be variously selected according to example embodiments.

The application servers 3100 to 3100n and the storage servers 3200 to 3200m may communicate with each other through a network 3300. The network 3300 may be implemented using a fiber channel (FC) or an Ethernet. The FC may be a medium used for a relatively high speed data transmission, and an optical switch that provides high performance and/or high availability may be used. The storage servers 3200 to 3200m may be provided as file storages, block storages or object storages according to an access scheme of the network 3300.

In some example embodiments, the network 3300 may be a storage-only network or a network dedicated to a storage such as a storage area network (SAN). For example, the SAN may be an FC-SAN that uses an FC network and is implemented according to an FC protocol (FCP). For another example, the SAN may be an IP-SAN that uses a transmission control protocol/internet protocol (TCP/IP) network and may be implemented according to an iSCSI (a SCSI over TCP/IP or an Internet SCSI) protocol. In other example embodiments, the network 3300 may be a general network such as the TCP/IP network. For example, the network 3300 may be implemented according to at least one of protocols such as an FC over Ethernet (FCoE), a network attached storage (NAS), a nonvolatile memory express (NVMe) over Fabrics (NVMe-oF), etc.

Hereinafter, example embodiments will be described based on the application server 3100 and the storage server 3200. The description of the application server 3100 may be applied to the other application server(s) 3100n, and the description of the storage server 3200 may be applied to the other storage server(s) 3200m.

The application server 3100 may store data requested to be stored by a user or a client into (at least) one of the storage servers 3200 to 3200m through the network 3300. In addition, the application server 3100 may obtain data requested to be read by the user or the client from (at least) one of the storage servers 3200 to 3200m through the network 3300. For example, the application server 3100 may be implemented as a web server or a database management system (DBMS).

The application server 3100 may access a memory 3120n or a storage device 3150n included in the other application server 3100n through the network 3300, and/or may access the memories 3220 to 3220m or the storage devices 3250 to 3250m included in the storage servers 3200 to 3200m through the network 3300. Thus, the application server 3100 may perform various operations on data stored in the application servers 3100 to 3100n and/or the storage servers 3200 to 3200m. For example, the application server 3100 may execute a command for moving or copying data between the application servers 3100 to 3100n and the storage servers 3200 to 3200m. The data may be transferred from the storage devices 3250 to 3250m of the storage servers 3200 to 3200m to the memories 3120 to 3120n of the application servers 3100 to 3100n directly or through the memories 3220 to 3220m of the storage servers 3200 to 3200m. For example, the data transferred through the network 3300 may be encrypted data for security or privacy.

In the storage server 3200, an interface 3254 of the storage device 3250 may provide a physical (and/or electrical) connection between the processor 3210 and a controller 3251 of the storage device 3250 and/or a physical (and/or electrical) connection between a network interface card (NIC) 3240 and the controller 3251. For example, the interface 3254 may be implemented based on a direct attached storage (DAS) scheme in which the storage device 3250 is directly connected with a dedicated cable. For example, the interface 3254 may be implemented based on at least one of various interface schemes such as an advanced technology attachment (ATA), a serial ATA (SATA) an external SATA (e-SATA), a small computer system interface (SCSI), a serial attached SCSI (SAS), a peripheral component interconnection (PCI), a PCI express (PCIe), an NVMe, a compute express link (CXL), an IEEE 1394, a universal serial bus (USB), a secure digital (SD) card interface, a multi-media card (MMC) interface, an embedded MMC (eMMC) interface, a universal flash storage (UFS) interface, an embedded UFS (eUFS) interface, a compact flash (CF) card interface, etc.

The storage server 3200 may further include a switch 3230 and the NIC 3240. The switch 3230 may selectively connect the processor 3210 with the storage device 3250 or may selectively connect the NIC 3240 with the storage device 3250 under a control of the processor 3210. Similarly, the application server 3100 may further include a switch 3130 and an NIC 3140.

In some example embodiments, the NIC 3240 may include a network interface card, a network adapter, or the like. The NIC 3240 may be connected to the network 3300 through a wired interface, a wireless interface, a Bluetooth interface, an optical interface, or the like. The NIC 3240 may further include an internal memory, a digital signal processor (DSP), a host bus interface, or the like, and may be connected to the processor 3210 and/or the switch 3230 through the host bus interface. The host bus interface may be implemented as one of the above-described examples of the interface 3254. In some example embodiments, the NIC 3240 may be integrated with at least one of the processor 3210, the switch 3230, and the storage device 3250.

In the storage servers 3200 to 3200m and/or the application servers 3100 to 3100n, the processor may transmit a command to the storage devices 3150 to 3150n and 3250 to 3250m or the memories 3120 to 3120n and 3220 to 3220m to program or read data. For example, the data may be error-corrected data by an error correction code (ECC) engine. For example, the data may be processed by a data bus inversion (DBI) or a data masking (DM), and may include a cyclic redundancy code (CRC) information. For example, the data may be encrypted data for security or privacy.

The storage devices 3150 to 3150n and 3250 to 3250m may transmit a control signal and command/address signals to NAND flash memory devices 3252 to 3252m of the storage devices 3250 and 3250m in response to a read command received from the processor. When data is read from the NAND flash memory devices 3252 to 3252m, a read enable (RE) signal may be input as a data output control signal and may serve to output data to a DQ bus. A data strobe signal (DQS) may be generated using the RE signal. The command and address signals may be latched in a page buffer based on a rising edge or a falling edge of a write enable (WE) signal.

The controller 3251 may control overall operations of the storage device 3250. In some example embodiments, the controller 3251 may include a static random access memory (SRAM). The controller 3251 may write data into the NAND flash memory device 3252 in response to a write command, or may read data from the NAND flash memory device 3252 in response to a read command. For example, the write command and/or the read command may be provided from the processor 3210 in the storage server 3200, the processor 3210m in the other storage server 3200m, or the processors 3110 to 3110n in the application servers 3100 to 3100n. A DRAM 3253 in the storage device 3250 may temporarily store (e.g., may buffer) data to be written to the NAND flash memory device 3252 or data read from the NAND flash memory device 3252. Further, the DRAM 3253 may store meta data. The meta data may be data generated by the controller 3251 to manage user data or the NAND flash memory device 3252.

Each of the storage devices 3250 to 3250m may be the storage device according to example embodiments. A form factor of each of the storage devices 3250 to 3250m may be efficiently changed and additional functions may be efficiently provided to each of the storage devices 3250 to 3250m, using the extension storage module according to example embodiments.

The example embodiments may be applied to various electronic devices and systems that include the storage devices. For example, the example embodiments may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, an automotive, etc.

The foregoing is illustrative of example embodiments and is not to be construed as limiting thereof. Although some example embodiments have been described, those skilled in the art will readily appreciate that many modifications are possible in the example embodiments without materially departing from the novel teachings and advantages of the example embodiments. Accordingly, all such modifications are intended to be included within the scope of the example embodiments as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A storage device comprising:
a main storage module; and
an extension storage module comprising:
a substrate;
a functional block on the substrate, wherein the functional block is configured to provide a first function for the main storage module;
a control circuit on the substrate, wherein the control circuit is configured to control the functional block;
a housing that extends around the substrate, the functional block, and the control circuit; and
a connector that is connected to the substrate, wherein the connector is configured to provide an electrical connection and a physical connection between the extension storage module and the main storage module,
wherein the extension storage module is electrically and physically attachable to and detachable from the main storage module through the connector, and
wherein in response to the extension storage module being detached from the main storage module, the main storage module has a first form factor.

2. The storage device of claim 1,
wherein, in response to the extension storage module being attached to the main storage module, the storage device has a second form factor, and
wherein the first form factor is different from the second form factor.

3. The storage device of claim 1, wherein the functional block includes:
an energy storage element that is configured to provide an auxiliary power supply voltage to the main storage module.

4. The storage device of claim 3, wherein the control circuit is configured to control the energy storage element to provide the auxiliary power supply voltage to the main storage module.

5. The storage device of claim 1, wherein the functional block comprises:
a cooling element that is configured to lower a temperature of the main storage module.

6. The storage device of claim 5, wherein the control circuit is configured to control the cooling element to lower the temperature of the main storage module.

7. The storage device of claim 1, wherein the housing has a rectangular parallelepiped shape, the housing comprising:
an upper surface and a lower surface that are parallel to each other; and
side surfaces that intersect the upper surface and the lower surface, and
wherein the connector is at least partially exposed from one of the upper surface, the lower surface, and the side surfaces of the housing.

8. The storage device of claim 1, wherein the housing has a two-step stair shape, the housing comprising:
an upper surface, a middle surface, and a lower surface that are parallel to each other, wherein each of the upper surface, the middle surface, and the lower surface has a rectangular shape;
a first side surface and a second side surface that intersect the upper surface, the middle surface, and the lower surface;
a third side surface that intersects the upper surface and the middle surface;
a fourth side surface that intersects the upper surface and the lower surface; and
a fifth side surface that intersects the middle surface and the lower surface, and
wherein the connector is at least partially exposed from the middle surface or the fifth side surface of the housing.

9. The storage device of claim 1, wherein the first form factor is E3.S, E3.S 2T, or E3.L 2T.

10. A storage device comprising:
a main storage module that has a first form factor; and
an extension storage module that is configured to be electrically and physically attachable to and detachable from the main storage module,
wherein the extension storage module comprises:
a first substrate;
a functional block on the first substrate, wherein the functional block is configured to provide a first function for the main storage module;
a control circuit on the first substrate, wherein the control circuit is configured to control the functional block;
a first housing that extends around the first substrate, the functional block, and the control circuit; and
a first connector that is connected to the first substrate, wherein the first connector is configured to provide an electrical connection and a physical connection with the main storage module, and
wherein in response to the extension storage module being attached to the main storage module, the storage device has a second form factor that is different from the first form factor.

11. The storage device of claim 10, wherein the main storage module comprises:
a second substrate;
a storage controller on the second substrate;
a plurality of nonvolatile memories on the second substrate, wherein the storage controller is configured to control the plurality of nonvolatile memories;
a buffer memory on the second substrate, wherein the storage controller is configured to control the buffer memory;
a second housing that extends around the second substrate, the storage controller, the plurality of nonvolatile memories, and the buffer memory; and
a second connector that is connected to the second substrate, wherein the second connector is configured to provide an electrical connection and a physical connection with the extension storage module.

12. The storage device of claim 11, wherein responsive to determining that the extension storage module is attached to the main storage module, the storage controller is configured to read module information from the extension storage module, to check the module information, and to transmit a request signal for the first function to the extension storage module based on the module information.

13. The storage device of claim 12, wherein the functional block includes:
an energy storage element that is configured to provide an auxiliary power supply voltage to the main storage module,
wherein the storage controller is configured to:
determine a dump size for a data dump operation based on the module information, and
perform the data dump operation based on the auxiliary power supply voltage provided from the extension storage module and the dump size responsive to determining that a data dump event has occurred, and
wherein responsive to determining that the data dump event has occurred, the storage controller is configured to move data from the buffer memory to the plurality of nonvolatile memories.

14. The storage device of claim 13, wherein responsive to determining that the data dump event has occurred, the storage controller is configured to generate a data dump command.

15. The storage device of claim 13, wherein responsive to determining that a voltage level of a main power supply voltage of the main storage module is lower than a reference voltage level, the storage controller is configured to determine that the data dump event has occurred.

16. The storage device of claim 11,
wherein the first housing has a first rectangular parallelepiped shape, the first housing comprising:
a first upper surface and a first lower surface that are parallel to each other; and
first side surfaces that intersect the first upper surface and the first lower surface,
wherein the second housing has a second rectangular parallelepiped shape, the second housing comprising:
a second upper surface and a second lower surface that are parallel to each other; and
second side surfaces that intersect the second upper surface and the second lower surface, and
wherein when the extension storage module is attached to the main storage module, one of the first upper surface and the first lower surface of the first housing and one of the second upper surface and the second lower surface of the second housing are in contact with each other.

17. The storage device of claim 11,
wherein the first housing has a first rectangular parallelepiped shape, the first housing comprising:
a first upper surface and a first lower surface that are parallel to each other; and
first side surfaces that intersect the first upper surface and the first lower surface,
wherein the second housing has a second rectangular parallelepiped shape, the second housing comprising:
a second upper surface and a second lower surface that are parallel to each other; and
second side surfaces that intersect the second upper surface and the second lower surface, and
wherein when the extension storage module is attached to the main storage module, one of the first side surfaces of the first housing and one of the second side surfaces of the second housing are in contact with each other.

18. The storage device of claim 11,
wherein the first housing has a two-step stair shape, the first housing comprising:
a first upper surface, a first middle surface, and a first lower surface that are parallel to each other, wherein each of the first upper surface, the first middle surface, and the first lower surface has a rectangular shape;
a first side surface and a second side surface that intersect the first upper surface, the first middle surface, and the first lower surface;
a third side surface that intersects the first upper surface and the first middle surface;
a fourth side surface that intersects the first upper surface and the first lower surface;
a fifth side surface that intersects the first middle surface and the first lower surface,
wherein the second housing has a rectangular parallelepiped shape, the second housing comprising:
a second upper surface and a second lower surface that are parallel to each other; and
sixth side surfaces that intersect the second upper surface and the second lower surface, and
wherein when the extension storage module is attached to the main storage module, the first middle surface of the first housing and one of the second upper surface and the second lower surface of the second housing are in contact with each other, and the fifth side surface of the first housing and one of the sixth side surfaces of the second housing are in contact with each other.

19. The storage device of claim 11, wherein the first housing and the second housing have a same width.

20. A solid state drive (SSD) device comprising:
a main module that has a first form factor; and
an extension module that is configured to be electrically and physically attachable to and detachable from the main module,
wherein the extension module comprises:
a first substrate;
an energy storage element on the first substrate, wherein the energy storage element is configured to provide an auxiliary power supply voltage to the main module;
an energy management circuit on the first substrate, wherein the energy management circuit is configured to control the energy storage element;
a first housing that extends around the first substrate, the energy storage element, and the energy management circuit; and
a first connector that is connected to the first substrate, wherein the first connector is configured to provide an electrical connection and a physical connection with the main module,
wherein the main module comprises:
a second substrate;
a storage controller on the second substrate;
a plurality of nonvolatile memories on the second substrate, wherein the storage controller is configured to control the plurality of nonvolatile memories;
a buffer memory on the second substrate, wherein the storage controller is configured to control the buffer memory;
a second housing that extends around the second substrate, the storage controller, the plurality of nonvolatile memories, and the buffer memory; and
a second connector that is connected to the second substrate, wherein the second connector is configured to provide an electrical connection and a physical connection with the extension module,
wherein when the main module is electrically and physically connected to the extension module through the first connector and the second connector, the SSD device has a second form factor that is different from the first form factor,
wherein the storage controller is configured to:
read module information from the extension module,
check the module information,
determine a dump size for a data dump operation based on the module information,
responsive to determining that a data dump event has occurred, transmit a power request signal to the energy management circuit based on at least one of a generation of a data dump command and a decrease in a voltage level of a main power supply voltage,
receive the auxiliary power supply voltage from the energy storage element, and
perform the data dump operation based on the auxiliary power supply voltage and the dump size, and
wherein responsive to determining that the data dump event has occurred, and the data dump operation is performed, the storage controller is configured to move data from the buffer memory to the plurality of nonvolatile memories.
